(19) United States
(12) Patent Application Publication
(10) Pub. No.: US 2017/0213960 A1
(43) Pub. Date: Jul. 27, 2017

(54) FABRICATION AND OPERATION OF CORRELATED ELECTRON MATERIAL DEVICES

(71) Applicant: ARM Ltd., Cambridge (GB)

(72) Inventors: Carlos Alberto Paz de Araujo, Colorado Springs, CO (US); Jolanta Bozena Celinska, Colorado Springs, CO (US); Kimberly Gay Reid, Austin, TX (US); Lucian Shifren, San Jose, CA (US)

(21) Appl. No.: 15/385,719

(22) Filed: Dec. 20, 2016

Related U.S. Application Data
(63) Continuation-in-part of application No. 15/046,177, filed on Feb. 17, 2016.
Application No. 15/046,177 is a continuation-in-part of application No. 15/006,889, filed on Jan. 26, 2016, now Pat. No. 9,627,615.

(51) Int. Cl. H01L 45/00; G11C 11/56

(52) U.S. Cl. CPC H01L 45/1616; H01L 45/1253; H01L 45/122; H01L 45/1641; G11C 11/5678

(57) ABSTRACT

Subject matter disclosed herein may relate to fabrication of correlated electron materials used, for example, to perform a switching function. In embodiments, a correlated electron material may comprise a dominant ligand and a substitutional ligand, which may permit electron donation and back-donation in a correlated electron material. Electron donation and back-donation may enable the correlated electron material to exhibit a transition from high impedance/insulative state to a low impedance conductive state.

### CROSS-REFERENCE TO RELATED APPLICATIONS

This application is a Continuation-In-Part of U.S. application Ser. No. 15/046,177, titled “FABRICATION OF CORRELATED ELECTRON MATERIAL DEVICES COMPRISING NITROGEN,” filed Feb. 17, 2016 and of U.S. application Ser. No. 15/006,889, titled “FABRICATION OF CORRELATED ELECTRON MATERIAL DEVICES,” filed Jan. 26, 2016, both of which are assigned to the assignee hereof and are expressly incorporated herein by reference.

### BACKGROUND

Field

This disclosure relates to correlated electron devices, and may relate, more particularly, to approaches toward fabricating correlated electron devices, such as may be used in switches, memory circuits, and so forth, which may exhibit desirable impedance characteristics.

Information

Integrated circuit devices, such as electronic switching devices, for example, may be found in a wide range of electronic device types. For example, memory and/or logic devices may incorporate electronic switches suitable for use in computers, digital cameras, smart phones, tablet devices, personal digital assistants, and so forth. Factors that relate to electronic switching devices, which may be of interest to a designer in considering whether an electronic switching device is suitable for a particular application, may include physical size, storage density, operating voltages, impedance ranges, and/or power consumption, for example. Other factors that may be of interest to designers may include, for example, cost of manufacture, ease of manufacture, scalability, and/or reliability. Moreover, there appears to be an ever-increasing need for memory and/or logic devices that exhibit characteristics of lower power and/or higher speed. However, conventional fabrication techniques, which may be well suited for certain types of memory and/or logic devices, may not be suitable for use in fabricating devices that utilize correlated electron materials.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1A is an illustration of a current density versus voltage profile of a device formed from a correlated electron material according to an embodiment;

FIG. 1B is an illustration of an embodiment of a switching device comprising a correlated electron material and a schematic diagram of an equivalent circuit of a correlated electron material switch;

FIG. 2 is an illustration of an embodiment of a switching device comprising filaments formed between conductive materials within a transition metal oxide film;

FIGS. 3A-3D are illustrations depicting electron donation and back-donation via sigma and pi bonds of a metal-carbonyl molecule in a correlated electron material according to an embodiment;

FIG. 3E shows a representative nickel oxide complex comprising a defect in the form of an oxygen vacancy in a correlated electron material, which may be repaired by the carbonyl molecule of FIGS. 3A-3D, according to an embodiment;

FIGS. 4A-4B are graphs depicting energy versus density of states in a nickel-based correlated electron material comprising oxygen as the dominant ligand according to an embodiment;

FIG. 5 is a flow diagram of an embodiment for a process for fabricating a correlated electron material;

FIGS. 6A-6C are flow diagrams of methods for fabricating correlated electron material films according to one or more embodiments;

FIG. 7 is a diagram of a Bis(cyclopentadienyl) molecule (Ni(C₅H₅)₂), which may function as an example precursor, in a gaseous form, utilized in fabrication of correlated electron material devices according to an embodiment;

FIGS. 8A-8D show sub-processes utilized in a method for fabricating a NiO-based film comprising correlated electron material devices according to an embodiment;

FIGS. 9A-9D are diagrams showing precursor flow and temperature profiles, as a function of time, which may be used in a method for fabricating correlated electron device materials, such as NiO-based devices, according to an embodiment;

FIGS. 9E-9H are diagrams showing precursor flow and temperature profiles, as a function of time, which may be used in a method for fabricating correlated electron device materials according to an embodiment;

FIGS. 10A-10C are diagrams showing temperature profiles, as a function of time, used in deposition and annealing processes for fabricating correlated electron material devices according to an embodiment;

FIG. 11A-11C are flow diagrams of methods for fabricating correlated electron material films using nitrogen-containing molecules according to one or more embodiments;

FIG. 12A is a diagram of nickel amidinate, which may function as a precursor to be utilized in fabrication of correlated electron material devices according to an embodiment;

FIG. 12B is a diagram of nickel 2-amino-pent-2-en-4-onato (Ni(apo)₂), which may function as a precursor to be utilized in fabrication of correlated electron material devices according to an embodiment;

FIGS. 13A-13D show sub-processes utilized in a method for fabricating correlated electron material devices according to an embodiment; and

FIGS. 14-18 are flow diagrams of embodiments for additional processes for fabricating correlated electron materials.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers to the context of the present disclosure.

Particular aspects of the present disclosure describe methods and/or processes for preparing and/or fabricating correlated electron materials (CEM) films to form, for example, a correlated electron switch, such as may be utilized to form a correlated electron random access memory (CERAM) in memory and/or logic devices, for example. Correlated electron materials, which may be utilized in the construction of CERAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects. In this context, a CEM switch, for example, may exhibit a substantially rapid conductor-to-insulator transition, which may be brought about by electron correlations rather than solid-state structural phase changes, such as in response to a change from a crystalline to an amorphous state, for example, in a phase change memory device or, in another example, nanoionic formation of filaments in resistive RAM (RERAM) devices. In one aspect, a substantially rapid conductor-to-insulator transition in a CEM device may be responsive to a quantum mechanical phenomenon, in contrast to melting/solidification or nanoionic filament formation, for example, in phase change and (RERAM) devices. Such quantum mechanical transitions between relatively conductive and relatively insulative states, and/or between first and second impedance states, for example, in a CEM may be understood in any one of several aspects. As used herein, the terms “relatively conductive state,” “relatively lower impedance state,” and/or “metal state” may be interchangeable, and/or may, at times, be referred to as a “relatively conductive/lower impedance state.” Similarly, the terms “relatively insulative state” and “relatively higher impedance state” may be used interchangeably herein, and/or may, at times, be referred to as a relatively “insulative/higher impedance state.”

In an aspect, a quantum mechanical transition of a correlated electron material between a relatively insulative/higher impedance state and a relatively conductive/lower impedance state, wherein the relatively conductive/lower impedance state is substantially dissimilar from the insulative/higher impedance state, may be understood in terms of a Mott transition. In accordance with a Mott transition, a material may switch from a relatively insulative/higher impedance state to a relatively conductive/lower impedance state if a Mott transition condition occurs. The Mott criteria may be defined by (n_{c})^{1/3} a≈0.26, wherein n_{c} denotes a concentration of electrons, and wherein “a” denotes the Bohr radius. If a threshold carrier concentration is achieved, such that the Mott criteria is met, the Mott transition is believed to occur. Responsive to the Mott transition occurring, the state of the CEM device changes from a relatively higher resistance/higher capacitance state (e.g., an insulative/higher impedance state) to a relatively lower resistance/lower capacitance state (e.g., a conductive/lower impedance state) that is substantially dissimilar from the higher resistance/higher capacitance state.

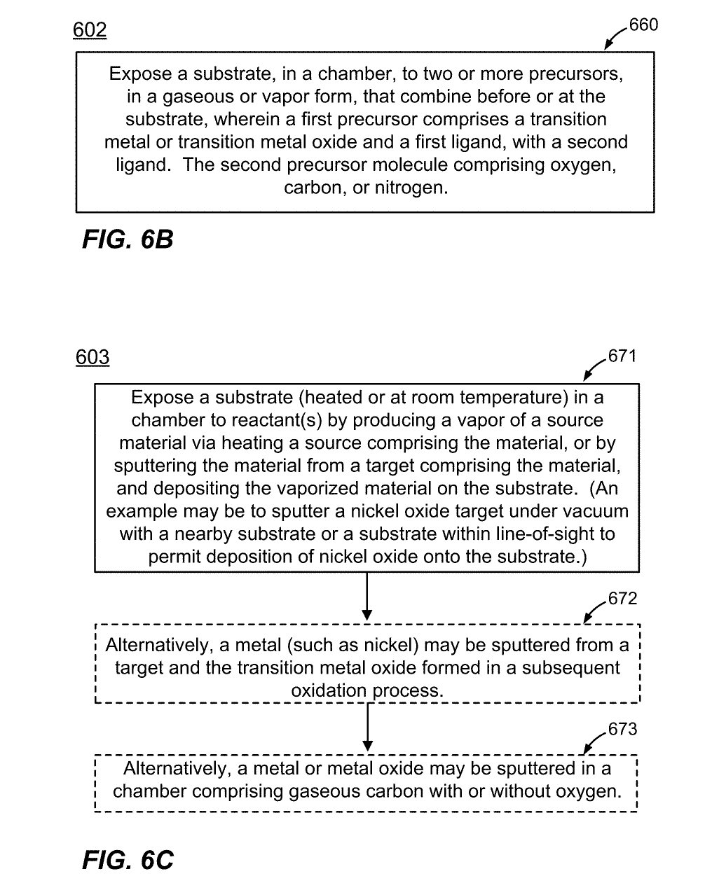

In another aspect, the Mott transition may be controlled by a localization of electrons. If carriers, such as electrons, for example, are localized, a strong coulomb interaction between the carriers is believed to split the bands of the CEM to bring about a relatively insulative (relatively higher impedance) state. If electrons are no longer localized, a weak coulomb interaction may dominate, which may give rise to a removal of band splitting, which may, in turn, bring about a transition to a metal (conductive) state (relatively lower impedance state) that is substantially dissimilar from the relatively higher (insulative) impedance state. Such a transition from metal to insulative states is shown and described further with respect to FIGS. 4A and 4B, herein.

Further, in an embodiment, switching from a relatively insulative/higher impedance state to a substantially dissimilar and relatively conductive/lower impedance state may bring about a change in capacitance in addition to a change in resistance. For example, a CEM device may exhibit a variable resistance together with a property of variable capacitance. In other words, impedance characteristics of a CEM device may include both resistive and capacitive components. For example, in a metal state, a CEM device may comprise a relatively low electric field that may approach zero, and therefore may exhibit a substantially low capacitance, which may likewise approach zero.

Similarly, in a relatively insulative/higher impedance state, which may be brought about by a higher density of bound or correlated electrons, an external electric field may be capable of penetrating the CEM and, therefore, the CEM may exhibit higher capacitance based, at least in part, on additional charges stored within the CEM. Thus, for example, a transition from a relatively insulative/higher impedance state to a substantially dissimilar and relatively conductive/lower impedance state in a CEM device may result in changes in both resistance and capacitance, at least in particular embodiments. Such a transition may bring about additional measurable phenomena, and claimed subject matter is not limited in this respect.

In an embodiment, a device formed from a CEM may exhibit switching of impedance states responsive to a Mott-transition in a majority of the volume of the CEM comprising a device. In an embodiment, a CEM may form a “bulk switch.” As used herein, the term “bulk switch” refers to at least a majority volume of a CEM switching a device's impedance state, such as in response to a Mott-transition. For example, in an embodiment, a significant portion of CEM of a device may switch from a relatively insulative/higher impedance state to a relatively conductive/lower impedance state or from a relatively conductive/lower impedance state to a relatively insulative/higher impedance state responsive to a Mott-transition. In an embodiment, a CEM may comprise one or more transition metals, or more transition metal compounds, one or more transition metal oxides (TMOs), one or more oxides comprising rare earth elements, one or more oxides of one or more d-block of f-block elements of the periodic table, one or more rare earth transitional metal oxide perovskites, yttrium, and/or ytterbium, although claimed subject matter is not limited in scope in this respect. In an embodiment, a CEM device may comprise one or more materials selected from a group comprising aluminum, cadmium, chromium, cobalt, copper, gold, iron, manganese, mercury, molybdenum, nickel, palladium, rhenium, ruthenium, silver, tantalum, tin, titanium, vanadium, yttrium, and zinc (which may be linked to an anion, such as oxygen or other types of ligands), or combinations thereof, although claimed subject matter is not limited in scope in this respect.

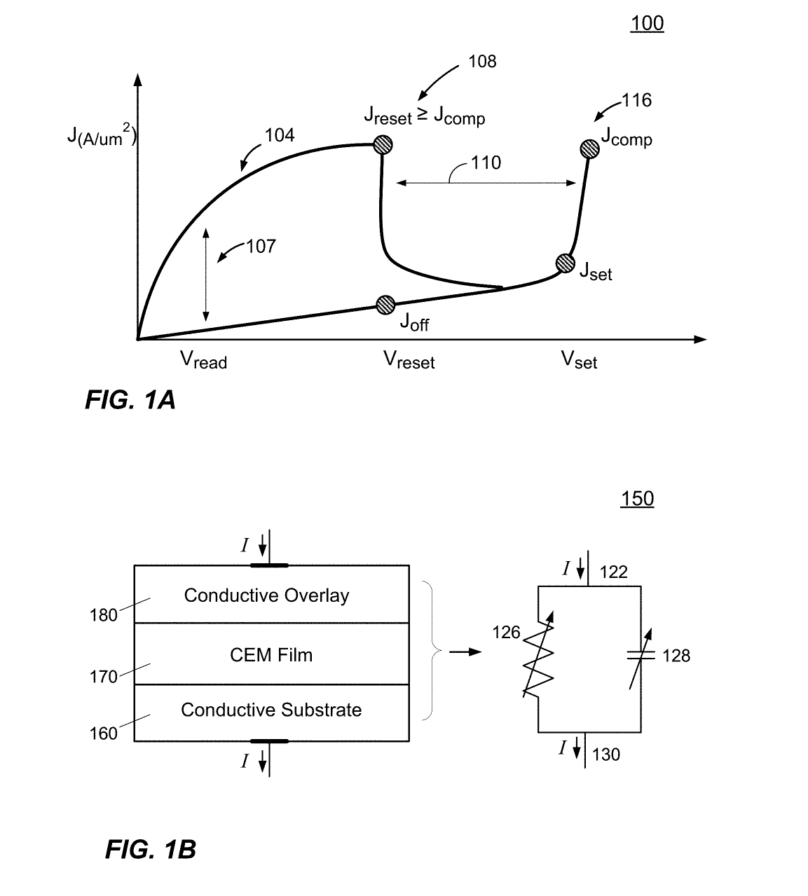

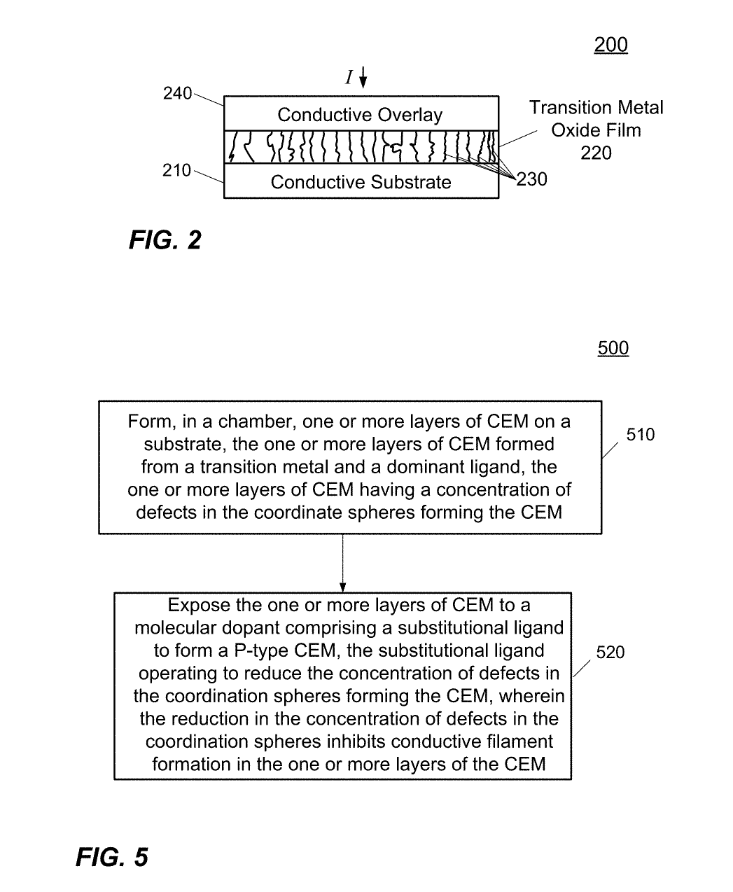

FIG. 1A is an illustration of an embodiment 100 of a current density versus voltage profile of a device formed from a correlated electron material. Based, at least in part, on a voltage applied to terminals of a CEM device, for example, during a “write operation,” the CEM device may be placed into a relatively low-impedance state or a relatively high-impedance state. For example, application of a voltage Vₛₑₜ and a current density Jₛₑₜ may bring about a transition of the CEM device to a relatively low-impedance memory state. Conversely, application of a voltage Vᵣₑₛₑₜ and a current density Jᵣₑₛₑₜ may bring about a transition of the CEM device to a relatively high-impedance memory state. As shown in FIG. 1A, reference designator 110 illustrates the voltage range that may separate Vₛₑₜ from Vᵣₑₛₑₜ. Following placement of the CEM device into a high-impedance state or a low-impedance state, the particular state of the CEM device may be detected by application of a voltage V_{read} (e.g., during a read operation) and detection of a current or current density at terminals of the CEM device (e.g., utilizing read window 107).

According to an embodiment, the CEM device characterized in FIG. 1A may comprise any transition metal oxide (TMO), such as, for example, perovskites, Mott insulators, charge exchange insulators, and Anderson disorder insulators. In particular implementations, a CEM device may be formed from switching materials, such as nickel oxide, cobalt oxide, iron oxide, yttrium oxide, titanium yttrium oxide, and perovskites, such as chromium doped strontium titanate, lanthanum titanate, and the manganate family including praseodymium calcium manganate, and praseodymium lanthanum manganite, just to provide a few examples. In particular, oxides incorporating elements with incomplete “d” and “f” orbital shells may exhibit sufficient impedance switching properties for use in a CEM device. Other implementations may employ other transition metal compounds without deviating from claimed subject matter.

In one aspect, the CEM device of FIG. 1A may comprise other types of transition metal oxide variable impedance materials, though it should be understood that these are exemplary only and are not intended to limit claimed subject matter. Nickel oxide (NiO) is disclosed as one particular TMO in which oxygen comprises the dominant ligand. Thus, in this context, a “dominant ligand,” as referred to herein, means a ligand occurring in the highest atomic concentration of a transition metal oxide or other type of transition metal, d-block-based, or f-block-based CEM. For example, in a nickel oxide-based CEM, in which oxygen comprises the dominant ligand, an atomic concentration of oxygen may exceed, for example, approximately 90.0%. It should be understood, however, that this is merely an example of a dominant ligand, and claimed subject matter is not limited in this respect.

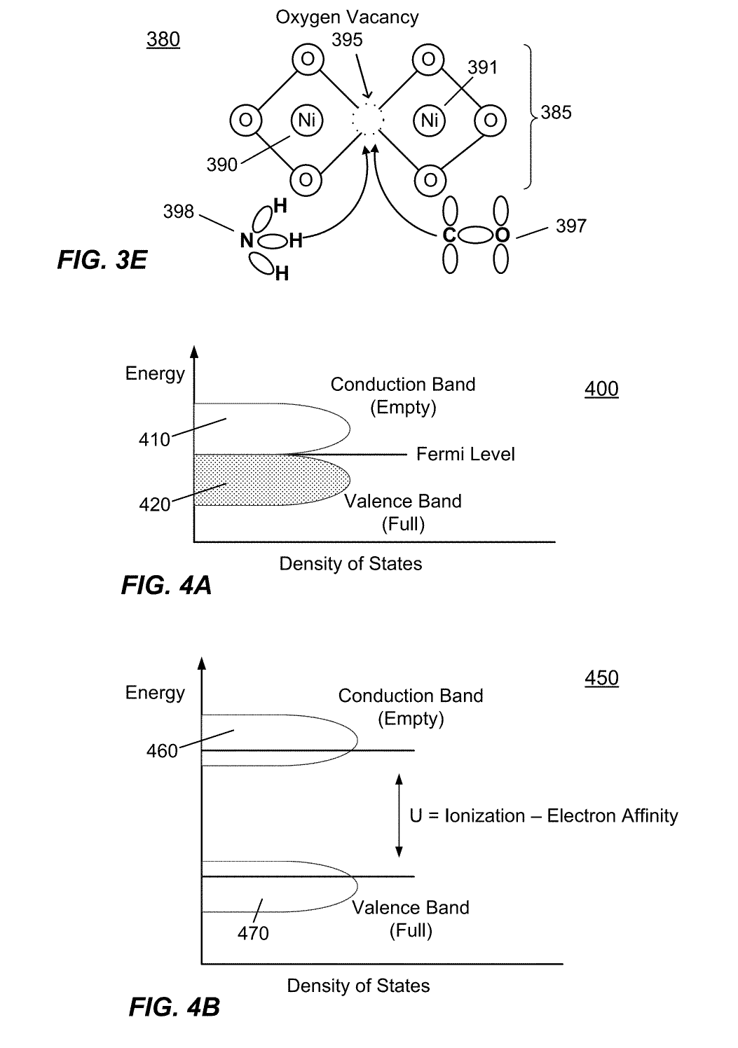

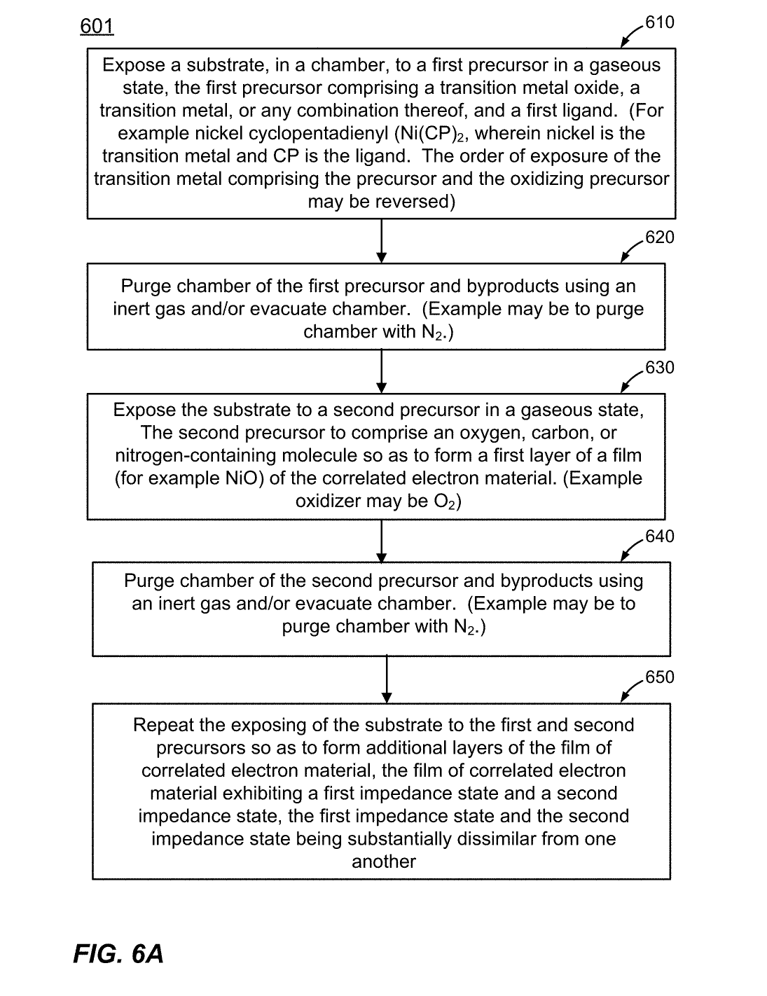

CEMs discussed herein may be doped with “extrinsic” or “substitutional” ligands, which may establish and/or stabilize variable impedance properties across a CEM film, for example. In this context, a “substitutional” ligand as referred to herein means a ligand that may be substituted for a dominant ligand in a transition metal molecule or other type of transition metal, d-block-based, or f-block-based CEM. For example, in a NiO-based CEM, a carbonyl (CO) molecule may be substituted for and oxygen atom, which brings about increased electrical conductivity for a CEM operating in a low-impedance state. In another example, in a NiO-based CEM, an ammonia (NH3) molecule may be substituted for an oxygen atom, which, again, brings about increased electrical conductivity for a CEM operating in a low-impedance state. A possible attribute of a substitutional ligand, at least in particular embodiments, may include performing an additional function of filling or supplanting vacancies, such as oxygen vacancies, for example, within coordination spheres of molecules that comprise a CEM. In this context, a “coordination sphere” as referred to herein means a central atom or ion in a particular molecular structure, and the atoms or molecules directly bound to the central atom or ion. A non-limiting example of a “coordination sphere” is illustrated in FIG. 3E.

In this context, a “CEM film” as referred to herein means a layer comprising an element or elements from group “d” or group “f” of the Periodic Table of the Elements. An attribute of such elements is partially filled “d” or “f” atomic orbitals and an ability for such elements to form a coordination sphere with a dominant ligands and substitutional (e.g. dopant) ligands. In this context, a “layer” as the term is used herein means a sheet or coating of material which may be disposed on or over an underlying formation, such as a substrate. For example, a layer deposited on an underlying substrate by way of an atomic layer deposition process may comprise a thickness of a single atom, comprising a thickness of a fraction of an angstrom (e.g., 0.6 Å). However, a layer encompasses a sheet or coating having a thickness greater than that of a single atom depending, for example, on a process utilized to fabricate films comprising a CEM film.

In embodiments, supplanting or filling of oxygen vacancies, for example, with substitutional ligands is believed to reduce occurrence of filament formation within a CEM such as in response to a change from a crystalline to an amorphous state, for example, in a phase change memory device or, in another example, nanoionic formation of filaments in resistive RAM (RERAM) devices. Further, supplanting or filling of oxygen vacancies, for example, with substitutional ligands is believed to reduce incidence of electron trapping within the CEM, which may operate to reduce parasitic device capacitance and increase device endurance. It should be understood, however, that use of substitutional ligands may influence other aspects of a CEM, and claimed subject matter is not limited in this respect. In embodiments, a substitutional ligand may comprise an atomic concentration approximately in the range of 0.1% and 10.0%. It should be understood, however, that the above-mentioned substitutional ligands are provided merely as examples, along with example concentrations, and claimed subject matter is not limited in this respect.

Thus, in another particular example, NiO doped with substitutional ligands may be expressed as where L may indicate a ligand element or compound, such as carbonyl (CO) or ammonia (NH₃), and x may indicate a number of units of the ligand for one unit of NiO. A value of x may be determined for any specific ligand and any specific combination of ligand with NiO or with any other transition metal compound simply by balancing valences. Other substitutional ligands, which may function as molecular dopants in addition to CO and NH₃ may include: nitrosyl (NO), triphenylphosphine (PPH₃), phenanthroline (C₁₂H₈N₂), bipyridine (C₁₀H₈N₂), ethylene (C₂H₄), ethylenediamine (C₂H₄(NH₂)₂), acetonitrile (CH₃CN), Fluorine (F), Chlorine (Cl), Bromine (Br), iodine, cyanide (CN), sulfur (S), selenium(Se), tellurium (Te), and sulfoselenides (SₓSe₁₋ₓ), sulfocyanides (SCN), and others.

In another embodiment, the CEM device of FIG. 1A may comprise other transition metal oxide variable impedance materials, such as nitrogen-containing ligands, though it should be understood that these are exemplary only and are not intended to limit claimed subject matter. Nickel oxide (NiO) is disclosed as one particular TMO. NiO materials discussed herein may be doped with substitutional nitrogen-containing ligands, which may stabilize variable impedance properties. In particular, NiO variable impedance materials disclosed herein may include nitrogen-containing molecules of the form CₓH_{y}N_{z} (wherein x≧0, y≧0, z≧0, and wherein at least x, y, or z comprise values >0) such as: ammonia (NH₃), cyano (CN⁻), azide ion (N₃⁻), ethylene diamine (C₂H₈N₂), phen(1,10-phenanthroline) (C₁₂H₈N₂), 2,2′bipyridine (C₁₀,H₈N₂), ethylenediamine ((C₂H₄(NH₂)₂), pyridine (C₅H₅N), acetonitrile (CH₃CN), and cyanosulfanides, such as thiocyanate (NCS), nitrosonium(NO), isoncyanides (RNC— organic compound with the functional group NEC, in which the organic fragment (R) is bonded to the isocyanide group by the nitrogen atom), alkenes, and alkynes, for example. NiO variable impedance materials disclosed herein may include members of an oxynitride family (NₓO_{y}, wherein x and y comprise whole numbers, and wherein x≧0 and y≧0 and at least x or y comprise values >0), which may include, for example, nitric oxide (NO), nitrous oxide (N₂O), nitrogen dioxide (NO₂), or precursors with an NO₃⁻ ligand. In embodiments, metal precursors comprising nitrogen-containing ligands, such as ligands amines, amides, alkylamides nitrogen-containing ligands with NiO by balancing valences.

In accordance with FIG. 1A, if sufficient bias is applied (e.g., exceeding a band-splitting potential (U=ionization−electron affinity), which will be described further with respect to FIGS. 4A and 4B) and the aforementioned Mott condition is satisfied (e.g., injected electron holes are of a population comparable to a population of electrons in a switching region, for example), a CEM device may transition from a relatively low-impedance state to a relatively high-impedance state, for example, responsive to a Mott transition. This may correspond to point 108 of the voltage versus current density profile of FIG. 1A. At, or suitably nearby this point, electrons are no longer screened and become localized near the metal ion. This correlation may result in a strong electron-to-electron interaction potential, which may operate to split the bands to form a relatively high-impedance material. If the CEM device comprises a relatively high-impedance state, current may be generated by transportation of electron holes. Consequently, if a threshold voltage is applied across terminals of the CEM device, electrons may be injected into a metal-insulator-metal (MIM) diode over the potential barrier of the MIM device. In certain embodiments, injection of a threshold current of electrons, at a threshold potential applied across terminals of a CEM device, may perform a “set” operation, which places the CEM device into a low-impedance state. In a low-impedance state, an increase in electrons may screen incoming electrons and remove a localization of electrons, which may operate to collapse the band-splitting potential, thereby giving rise to the low-impedance state.

According to an embodiment, current in a CEM device may be controlled by an externally applied “compliance” condition, which may be determined at least partially on the basis of an applied external current, which may be limited during a write operation, for example, to place the CEM device into a relatively high-impedance state. This externally-applied compliance current may, in some embodiments, also set a condition of a current density for a subsequent reset operation to place the CEM device into a relatively high-impedance state. As shown in the particular implementation of FIG. 1A, a current density J_{comp} may be applied during a write operation at point 116 to place the CEM device into a relatively low-impedance state, and may determine a compliance condition for placing the CEM device into a high-impedance state in a subsequent write operation. As shown in FIG. 1A, the CEM device may be subsequently placed into a low-impedance state by application of a current density Jᵣₑₛₑₜ≧J_{comp} at a voltage Vᵣₑₛₑₜ at point 108, at which J_{comp} is externally applied.

In embodiments, compliance may set a number of electrons in a CEM device that may be “captured” by holes for the Mott transition. In other words, a current applied in a write operation to place a CEM device into a relatively low-impedance memory state may determine a number of holes to be injected to the CEM device for subsequently transitioning the CEM device to a relatively high-impedance memory state.

As pointed out above, a reset condition may occur in response to a Mott transition at point 108. As pointed out above, such a Mott transition may bring about a condition in a CEM device, which resembles a P-type doped semiconductor, in which a concentration of electrons n approximately equals, or becomes at least comparable to, a concentration of electron holes p. This condition may be modeled according to expression (1) as follows:

$${λ}_{TF} {n}^{\frac{1}{3}} = C ∼ 0.26 \\ n = {( \frac{C}{{λ}_{TF}} )}^{3} \qquad ( 1 )$$

In expression (1), λ_{TF} corresponds to a Thomas Fermi screening length, and C is a constant.

According to an embodiment, a current or current density in region 104 of the voltage versus current density profile shown in FIG. 1A, may exist in response to injection of holes from a voltage signal applied across terminals of a CEM device. Here, injection of holes may meet a Mott transition criterion for the low-impedance state to high-impedance state transition at current I_{MI} as a threshold voltage V_{MI} is applied across terminals of a CEM device. This may be modeled according to expression (2) as follows:

$${I}_{MI} ( {V}_{MI} ) = \frac{dQ ( {V}_{MI} )}{dt} \approx \frac{Q ( {V}_{MI} )}{t} \\ Q ( {V}_{MI} ) = qn ( {V}_{MI} ) \qquad ( 2 )$$

Where Q(V_{MI}) corresponds to the charged injected (holes or electrons) and is a function of an applied voltage. Injection of electrons and/or holes to enable a Mott transition may occur between bands and in response to threshold voltage V_{MI}, and threshold current I_{MI}. By equating electron concentration n with a charge concentration to bring about a Mott transition by holes injected by I_{MI} in expression (2) according to expression (1), a dependency of such a threshold voltage V_{MI} on Thomas Fermi screening length λTF may be modeled according to expression (3), as follows:

$${I}_{MI} ( {V}_{MI} ) = \frac{Q ( {V}_{MI} )}{t} = \frac{qn ( {V}_{MI} )}{t} = \frac{q}{t} {( \frac{C}{{λ}_{TF}} )}^{3} \\ {J}_{reset} ( {V}_{MI} ) = {J}_{MI} ( {V}_{MI} ) = \frac{{I}_{MI} ( {V}_{MI} )}{{A}_{CEM}} = \frac{q}{{A}_{{CEM}^{1}}} {( \frac{C}{{λ}_{TF} ( {V}_{MI} )} )}^{3} \qquad ( 3 )$$

In which A_{CEM} is a cross-sectional area of a CEM device; and Jᵣₑₛₑₜ(V_{MI}) may represent a current density through the CEM device to be applied to the CEM device at a threshold voltage V_{MI}, which may place the CEM device into a relatively high-impedance state.

FIG. 1B is an illustration of an embodiment 150 of a switching device comprising a correlated electron material and a schematic diagram of an equivalent circuit of a correlated electron material switch. As previously mentioned, a correlated electron device, such as a CEM switch, a CERAM array, or other type of device utilizing one or more correlated electron materials may comprise variable or complex impedance device that may exhibit characteristics of both variable resistance and variable capacitance. In other words, impedance characteristics for a CEM variable impedance device, such as a device comprising a conductive substrate 160, CEM 170, and conductive overlay 180, may depend at least in part on resistance and capacitance characteristics of the device if measured across device terminals 122 and 130. In an embodiment, an equivalent circuit for a variable impedance device may comprise a variable resistor, such as variable resistor 126, in parallel with a variable capacitor, such as variable capacitor 128. Of course, although a variable resistor 126 and variable capacitor 128 are depicted in FIG. 1B as comprising discrete components, a variable impedance device, such as device of embodiment 150, may comprise a substantially homogenous CEM and claimed subject matter is not limited in this respect.

Table 1 below depicts an example truth table for an example variable impedance device, such as the device of embodiment 150.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied})~0 | Z_{low}(V_{applied}) |

In an embodiment, Table 1 shows that a resistance of a variable impedance device, such as the device of embodiment 150, may transition between a low-impedance state and a substantially dissimilar, high-impedance state as a function at least partially dependent on a voltage applied across the CEM device. In an embodiment, an impedance exhibited at a low-impedance state may be approximately in the range of 10.0-100,000.0 times lower than an impedance exhibited in a high-impedance state. In other embodiments, an impedance exhibited at a low-impedance state may be approximately in the range of 5.0 to 10.0 times lower than an impedance exhibited in a high-impedance state, for example. It should be noted, however, that claimed subject matter is not limited to any particular impedance ratios between high-impedance states and low-impedance states. Table 1 shows that a capacitance of a variable impedance device, such as the device of embodiment 150, may transition between a lower capacitance state, which, in an example embodiment, may comprise approximately zero (or very little) capacitance, and a higher capacitance state that is a function, at least in part, of a voltage applied across the CEM device.

According to an embodiment, a CEM device, which may be utilized to form a CEM switch, a CERAM memory device, or a variety of other electronic devices comprising one or more correlated electron materials, may be placed into a relatively low-impedance memory state, such as by transitioning from a relatively high-impedance state, for example, via injection of a sufficient quantity of electrons to satisfy a Mott transition criteria. In transitioning a CEM device to a relatively low-impedance state, if enough electrons are injected and the potential across the terminals of the CEM device overcomes a threshold switching potential (e.g., Vₛₑₜ), injected electrons may begin to screen. As previously mentioned, screening may operate to unlocalize double-occupied electrons to collapse the band-splitting potential (U), thereby bringing about a relatively low-impedance state.

In particular embodiments, changes in impedance states of CEM devices, such as changes from a low-impedance state to a substantially dissimilar high-impedance state, for example, may be brought about by “donation” and “back-donation” of electrons of materials comprising transition metals, transition metal oxides (such as NixOy, wherein the subscripts “x” and “y” comprise whole numbers), d-block metals, or f-block metals. In this context, as the term is used herein, “donation” of electrons, as described in greater detail with respect to FIGS. 3A-3D, means supplying of one or more electrons to a transition metal, transition metal oxide, d-block metal or f-block metal, or any combination thereof, by an adjacent molecule of a coordination sphere, for example, comprising the transition metal, transition metal oxide, D-block metal or F block metal, or combination thereof. As the term is used herein, “back-donation” of electrons, also as described in greater detail with respect to FIGS. 3A-3D, refers to an accepting of one or more electrons by an adjacent molecule of a coordination sphere, for example, comprising a dominant or substitutional ligand. Donation and back-donation of electrons may permit a transition metal, transition metal compound, transition metal oxide, d-block metal or f-block metal, or a combination thereof, to maintain an ionization state that permits impedance to be controlled under an influence of an applied voltage. In certain embodiments, donation and back-donation in a CEM, for example, may be enhanced responsive to use of a carbon-containing dopant, such as carbonyl (CO), or a nitrogen-containing dopant, such as ammonia (NH₃), ethylene diamine (C₂H₈N₂), or members of an oxynitride family (NA), for example, which may permit a CEM to exhibit a property in which electrons are controllably, and reversibly, donated to a conduction band of the transition metal or transition metal oxide, such as nickel, for example, during operation of a device or circuit comprising a CEM. In embodiments, donation may be reversed, for example, in nickel oxide material (e.g., NiO:CO or NiO:NH₃), thereby permitting the nickel oxide material to transition from exhibiting a high-impedance property to exhibiting a low-impedance property during device operation.

Thus, in this context, a donating/back-donating material refers to a material that exhibits an impedance switching property, such as switching from a first impedance state to a substantially dissimilar second impedance state (e.g., from a relatively low impedance state to a relatively high impedance state, or vice versa) based, at least in part, on influence of an applied voltage to control donation of electrons, and reversal of the electron donation (back-donation), to and from a conduction band of the material.

As described in greater detail with respect to FIGS. 4A and 4B, by way of electron donation, a CEM switch comprising a transition metal, transition metal compound, or a transition metal oxide, may exhibit low-impedance/low-capacitance properties if the transition metal, such as nickel, for example, is placed into an oxidation state of 2+(e.g., Ni²⁺ in a material such as NiO:CO or NiO:NH₃). Conversely, electron donation may be reversed if a transition metal, such as Ni, for example, is placed into an oxidation state of 1+ or 3+. Accordingly, during operation of a CEM device, back-donation may result in “disproportionation,” which may comprise a substantially simultaneous oxidation and reduction reaction, substantially in accordance with expression (4), below:

2Ni²⁺→Ni¹⁺+Ni³⁺ (4)

Such disproportionation, in this instance, refers to formation of nickel ions as Ni¹⁺+Ni³⁺ as shown in expression (4), which may bring about, for example, a relatively high-impedance state during operation of the CEM device. Electron donation may give rise to the reversal of the disproportionation reaction of expression (4) substantially in accordance with expression (5), below:

Ni¹⁺Ni³⁺→2Ni²⁺ (5)

In this context, a “molecular dopant” as referred to herein, means an atomic or molecular species that enables local, such as within a coordination sphere of a CEM, electron donation/back-donation to/from a transition metal, transition metal oxide, d-block-based, or f-block-based metal that comprises the CEM. Thus, within a coordination sphere, electron donation to a metal from a molecular dopant may bring about a low-impedance state of the CEM. Additionally, within a coordination sphere, electron back-donation from a metal to a molecular dopant may bring about a high-impedance state of the CEM. In an embodiment, a “molecular dopant” such as a carbon-containing ligand (e.g., CO) or a nitrogen-containing ligand, (e.g., NH₃), may permit sharing of electrons during operation of the CEM device to bring about the disproportionation, and its reversal, of expressions (4) and (5).

As described with reference to FIGS. 3A-3D, a class of molecular dopants including certain molecules, such as CO and NH₃, operate locally to or within a coordination sphere to donate electrons from, for example, a sigma bond. In an embodiment, such a sigma bond may be formed between a carbon and an oxygen atom and may back-donate electrons from a pi bond of a metal atom. Molecular dopants additionally encompass certain single-atom species, such as halides (e.g., Cl, Br, F, and so forth) that operate local to a coordination sphere of a CEM, to donate/back-donate electrons. Donation of electrons within molecular doped CEMs operate to decrease an energy gap between conduction and valence bands of a metal atom in a coordination sphere, while back-donation of electrons within molecular doped CEMs may operate to increase energy between conduction and valence bands of the metal ion in a coordination sphere. An example theoretical operation of single-atom molecular dopants is described with reference to FIGS. 4A-4B.

In this context, a “sigma bond” as referred to herein means a covalent chemical bond formed by the axial overlapping of atomic orbitals. In a CO molecule, for example, a sigma bond refers to an electron that may be “shared” between the carbon and oxygen atoms. It should be understood, however, that this is merely an example of a sigma bond, and that claimed subject matter is not limited in this respect. Also in this context, a “pi bond” as referred to herein means a covalent bond that results from a formation of a molecular orbital by side-to-side overlap of atomic orbitals of the involved atoms. In a CO molecule, for example, a pi bond refers to the side-to-side orbits of the CO molecule, such as given by 322 and 324 in FIGS. 3A-3B. It should be understood, however, that this merely an example of a pi bond, and claimed subject matter is not limited in this respect.

It should be understood that CO, NH₃, Cl, Br, and F, are merely examples of molecular dopants, and that other types of molecular dopants such as cyano (CN⁻), azide ion (N₃⁻), ethylene diamine (C₂H₈N₂), phen(1,10-phenanthroline) (C₁₂H₈N₂), 2,2′bipyridine (C₁₀,H₈N₂), ethylenediamine ((C₂H₄(NH₂)₂), pyridine (C₅H₅N), acetonitrile (CH₃CN), and cyanosulfanides may similarly provide electron donation/back-donation to bring about CEM operation in a low-impedance state and a high-impedance state, and that claimed subject matter is not limited in this respect.

In embodiments, concentration of molecular dopants, such as carbonyl (to form NiO:CO) and ammonia (to form NiO:NH₃), for example, may vary from values approximately in the range of an atomic percentage of 0.1% to 10.0%. Such concentrations may influence Vᵣₑₛₑₜ and Vₛₑₜ, as shown in FIG. 1A, which may vary approximately in the range of 0.1 V to 10.0 V subject to the condition that Vₛₑₜ≧Vᵣₑₛₑₜ. For example, in one possible embodiment, Vᵣₑₛₑₜ may occur at a voltage approximately in the range of 0.1 V to 1.0 V, and Vₛₑₜ may occur at a voltage approximately in the range of 1.0 V to 2.0 V, for example. It should be noted, however, that variations in Vₛₑₜ and Vᵣₑₛₑₜ may occur based, at least in part, on a variety of factors, such as atomic concentration of a donating/back-donating material, such as NiO:CO or NiO:NH₃ and other materials present in the CEM device, as well as other process variations, and claimed subject matter is not limited in this respect.

In certain embodiments, atomic layer deposition (ALD) may be utilized to form or to fabricate films comprising NiO materials, such as NiO:CO or NiO:NH₃, to permit donation of electrons during operation of the CEM device in a circuit environment, for example, to give rise to a low-impedance/low-capacitance state. Also during operation in a circuit environment, for example, electron donation may be reversed so as to give rise to a substantially dissimilar impedance state, such as a high-impedance state, for example. In particular embodiments, atomic layer deposition may utilize two or more precursors to deposit components of, for example, NiO:CO or NiO:NH₃, or other transition metal oxide, transition metal, or combination thereof, onto a conductive substrate. In an embodiment, layers of a CEM device may be deposited utilizing separate precursor molecules, AX and BY, according to expression (6a), below:

AX_{(gas)}+BY_{(gas)}=AB_{(solid)}+XY_{(gas)} (6a)

Wherein “A” of expression (6a) corresponds to a transition metal, transition metal compound, transition metal oxide, or any combination thereof. In embodiments, a transition metal oxide may comprise nickel, but may comprise other transition metals, transition metal compound, and/or transition metal oxides, such as aluminum, cadmium, chromium, cobalt, copper, gold, iron, manganese, mercury, molybdenum, nickel palladium, rhenium, ruthenium, silver, tantalum, tin, titanium, vanadium yttrium, and zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

In embodiments, “X” of expression (6a) may comprise a ligand, such as organic ligand, comprising amidinate (AMD), dicyclopentadienyl (Cp)₂, diethylcyclopentadienyl (EtCp)₂, Bis(2,2,6,6-tetramethylheptane-3,5-dionato) ((thd)₂), acetylacetonate (acac), bis(methylcyclopentadienyl) ((CH₃C₅H₄)₂), dimethylglyoximate (dmg)2,2-amino-pent-2-en-4-onato (apo)₂, (dmamb)₂ where dmamb=1-dimethylamino-2-methyl-2-butanolate, (dmamp)2 where dmamp=1-dimethylamino-2-methyl-2-propanolate, Bis(pentamethylcyclopentadienyl) (C₅(CH₃)₅)₂ and carbonyl (CO)₄. Accordingly, in some embodiments, nickel-based precursor AX may comprise, for example, nickel amidinate (Ni(AMD)), nickel dicyclopentadienyl (Ni(Cp)₂), nickel diethyl cyclopentadienyl (Ni(EtCp)₂), Bis(2,2,6,6-tetramethylheptane-3,5-dionato)Ni(II) (Ni(thd)₂), nickel acetylacetonate (Ni(acac)₂), bis(methylcyclopentadienyl)nickel (Ni(CH₃C₅H₄)₂, Nickel dimethylglyoximate (Ni(dmg)₂), Nickel 2-amino-pent-2-en-4-onato (Ni(apo)₂), Ni(dmamb)₂ where dmamb=1-dimethylamino-2-methyl-2-butanolate, Ni(dmamp)₂ where dmamp=1-dimethylamino-2-methyl-2-propanolate, Bis(pentamethylcyclopentadienyl) nickel (Ni(C₅(CH₃)₅)₂, and nickel carbonyl (Ni(CO)₄), just to name a few examples. In expression (6a), precursor “BY” may comprise an oxidizer, such as oxygen (O₂), ozone (O₃), nitric oxide (NO), hydrogen peroxide (H₂O₂), just to name a few examples. In other embodiments as will be described further herein, plasma may be used with an oxidizer to form oxygen radicals.

However, in particular embodiments, a dopant comprising an electron donating/back-donating material, in addition to precursors AX and BY, may be utilized to form layers of the CEM device. An additional dopant ligand comprising an electron donating/back-donating material, which may co-flow with precursor AX, may permit formation of donating/back-donating compounds, substantially in accordance with expression (6b), below. In embodiments, a dopant comprising a donating/back-donating material, such as ammonia (NH₃), methane (CH₄), carbon monoxide (CO), or other material may be utilized, as may other ligands comprising carbon or nitrogen or other dopants comprising donating/back-donating materials listed above. Thus, expression (6a) may be modified to include an additional dopant ligand comprising a donating/back-donating material substantially in accordance with expression (6b), below:

AX_{(gas)}+(NH₃ or other ligand comprising nitrogen)+BY_{(gas)}=AB:NH_{3(solid)}+XY_{(gas)} (6b)

It should be noted that concentrations, such as atomic concentration, of precursors, such as AX, BY, and NH₃ (or other ligand comprising nitrogen) of expressions (6a) and (6b) may be adjusted so as to bring about a final atomic concentration of nitrogen-based or carbon-based dopant molecules comprising a donating/back-donating material in a fabricated CEM device, such as in the form of ammonia (NH₃) or carbonyl (CO) comprising a concentration of between approximately 0.1% and 10.0%. However, claimed subject matter is not necessarily limited to the above-identified precursors and/or atomic concentrations. Rather, claimed subject matter is intended to embrace all such precursors utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, or the like, utilized in fabrication of CEM devices. In expressions (6a) and (6b), “BY” may comprise an oxidizer, such as oxygen (O₂), ozone (O₃), nitric oxide (NO), hydrogen peroxide (H₂O₂), just to name a few examples. In other embodiments, plasma may be used with an oxidizer (BY) to form oxygen radicals. Likewise, plasma may be used with the doping species comprising a donating/back-donating material to form an activated species to control the doping concentration of the CEM.

In particular embodiments, such as embodiments utilizing atomic layer deposition, a substrate may be exposed to precursors, such as AX and BY, as well as dopants comprising electron donating/back-donating materials (such as ammonia or other ligands comprising metal-nitrogen bonds, including, for example, nickel-amides, nickel-imides, nickel-amidinates, or combinations thereof) in a heated chamber, which may attain, for example, a temperature approximately in the range of 20.0° C. to 1000.0° C., for example, or between temperatures approximately in the range of 20.0° C. and 500.0° C. in certain embodiments. In one particular embodiment, in which atomic layer deposition of NiO:NH₃, for example, is performed, chamber temperature ranges approximately in the range of 20.0° C. and 400.0° C. may be utilized. Responsive to exposure to precursor gases (e.g., AX, BY, NH₃, or other ligand comprising nitrogen), such gases may be purged from the heated chamber for durations approximately in the range of 0.5 seconds to 180.0 seconds. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression 6(a)) or a single three-precursor cycle (e.g., AX, NH₃, CH₄, or other ligand comprising nitrogen, carbon or other dopant comprising an electron donating/back-donating material, and BY, as described with reference to expression 6(b)) utilizing atomic layer deposition may bring about a CEM device layer comprising a thickness approximately in the range of 0.6 Å to 5.0 Å per cycle). Accordingly, in an embodiment, to form a CEM device film comprising a thickness of approximately 500.0 Å utilizing an atomic layer deposition process in which layers comprise a thickness of approximately 0.6 Å, 800-900 cycles, for example, may be utilized. In another embodiment, utilizing an atomic layer deposition process in which layers comprise approximately 5.0 Å, 100 two-precursor cycles, for example. It should be noted that atomic layer deposition may be utilized to form CEM device films having other thicknesses, such as thicknesses approximately in the range of 1.5 nm and 150.0 nm, for example, and claimed subject matter is not limited in this respect.

In particular embodiments, responsive to one or more two-precursor cycles (e.g., AX and BY), or three-precursor cycles (AX, NH₃, CH₄ or other ligand comprising nitrogen, carbon or other dopant comprising a donating/back-donating material and BY), of atomic layer deposition, a CEM device film may undergo in situ annealing, which may permit improvement of film properties or may be used to incorporate the dopant comprising an electron donating/back-donating material, such as in the form of carbonyl or ammonia, in the CEM device film. In certain embodiments, a chamber may be heated to a temperature approximately in the range of 20.0° C. to 1000.0° C. However, in other embodiments, in situ annealing may be performed utilizing chamber temperatures approximately in the range of 100.0° C. to 800.0° C. In situ annealing times may vary from a duration approximately in the range of 1.0 seconds to 5.0 hours. In particular embodiments, annealing times may vary within more narrow ranges, such as, for example, from approximately 0.5 minutes to approximately 180.0 minutes, for example, and claimed subject matter is not limited in these respects.

In particular embodiments, a CEM device manufactured in accordance with the above-described process may exhibit a “born on” property in which the device exhibits relatively low impedance (relatively high conductivity) immediately after fabrication of the device. Accordingly, if a CEM device is integrated into a larger electronics environment, for example, at initial activation a relatively small voltage applied to a CEM device may permit a relatively high current flow through the CEM device, as shown by region 104 of FIG. 1A. For example, as previously described herein, in at least one possible embodiment, Vᵣₑₛₑₜ may occur at a voltage approximately in the range of 0.1 V to 1.0 V, and Vₛₑₜ may occur at a voltage approximately in the range of 1.0 V to 2.0 V, for example. Accordingly, electrical switching voltages operating in a range of approximately 2.0 V, or less, may permit a memory circuit, for example, to write to a CERAM memory device, to read from a CERAM memory device, or to change state of a CERAM switch, for example. In embodiments, such relatively low voltage operation may reduce complexity, cost, and may provide other advantages over competing memory and/or switching device technologies.

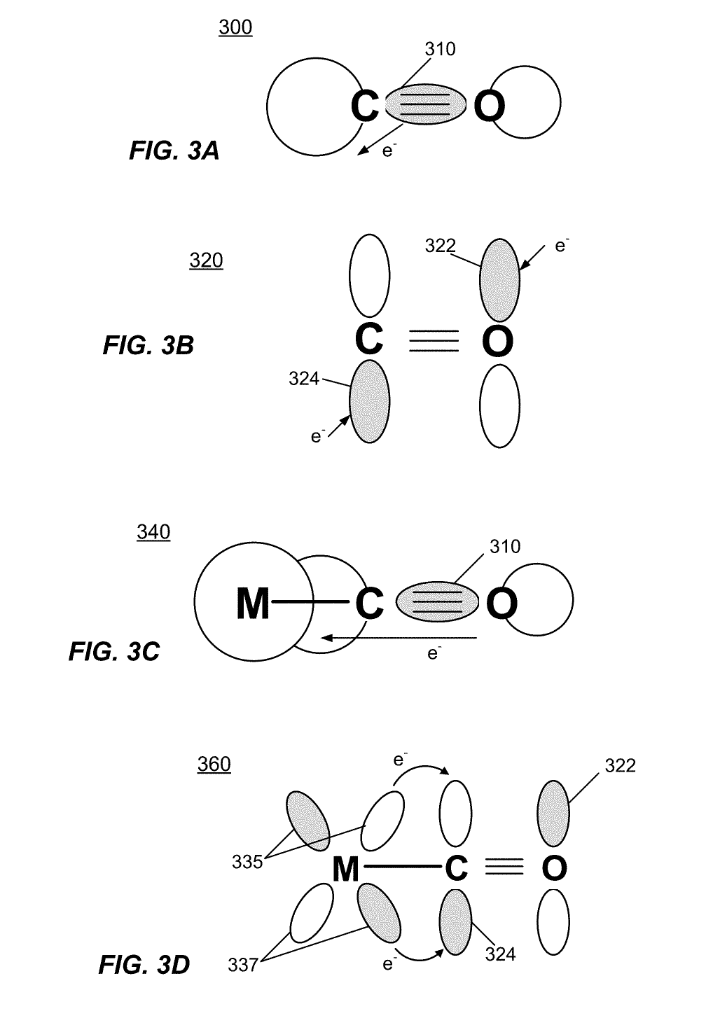

FIG. 2 is an illustration of an embodiment of a switching device comprising filaments formed between conductive materials within a transition metal oxide film. A conductive substrate, such as conductive substrate 210, for example, may comprise a titanium-based and/or a titanium-containing substrate, such as titanium nitride (TiN), fabricated in layers, for example, for use in a CERAM switching device or for use in any other type of CEM-based device. In other embodiments, conductive substrate 210 may comprise other types of conductive materials, such as titanium nitride, platinum, titanium, copper, aluminum, cobalt, nickel, tungsten, tungsten nitride, cobalt silicide, ruthenium oxide, chromium, gold, palladium, indium tin oxide, tantalum, silver, iridium, or any combination thereof. In other embodiments, conductive substrate 210 may comprise a tantalum-based and/or a tantalum-containing material, such as tantalum nitride (TaN), formed in layers, for use in a CERAM device or for use in any other type of CEM-based device and claimed subject matter is not limited in this respect. In embodiments, a TaN substrate may be formed utilizing precursors such as pentakisdimethylamido tantalum (PDMAT), for example.

In other embodiments, conductive substrate 210 may comprise a tungsten-based and/or a tungsten-containing material formed in layers, such as tungsten-nitride (WN), for example, for use in a CERAM device or other type of CEM-based device. In embodiments, a WN substrate may be formed utilizing precursors such as tungsten hexacarbonyl (W(CO)₆) and/or cyclopentadienyltungsten(II) tricarbonyl hydride, for example. In another embodiment, a WN substrate may be formed utilizing triamminetungsten tricarbonyl ((NH₃)3 W(CO)₃) and/or tungsten pentacarbonyl methylbutylisonitrile (W(CO)5(C₅H₁₁NC), or, for example. Conductive overlay 240 may comprise one or more materials similar to materials comprising conductive substrate 210, for example, or may comprise an entirely different material, and claimed subject matter is not limited in this respect.

In particular embodiments, responsive to application of a voltage within a particular range, filaments 230 may form between a conductive substrate 210 and conductive overlay 240. In certain embodiments, filaments may represent low-resistance crystalline paths between conductive substrate 210 and conductive overlay 240. As previously described, filament formation may comprise one or more nanoionic oxidation-reduction (redox) reactions in which a transition metal oxide film may become oxidized, for example. In other embodiments, filament formation may be brought about by ionic transport that utilizing a vacancy-ion diffusion process.

However, although formation of filaments 230 within a transition metal oxide film 220 may permit the device to perform switching operations responsive to application of voltage levels of approximately in the range of 3.0 V or less, for example, filament formation may preclude or impede the switching device from operating in accordance with quantum mechanical correlated electron phenomena. For example, filament formation may permit accumulation of parasitic electrical charges within a device constructed from a transition metal oxide film, which may give rise to increased parasitic device capacitance. Accordingly, with increased parasitic capacitance high frequency operation of a CEM device may be impaired.

Accordingly, in certain embodiments, it may be advantageous to reduce or eliminate formation of conductive filaments so as to allow a low-impedance, low capacitance, path for electrical current flowing between a conductive substrate 210 and conductive overlay 240. Avoidance of filament formation in a CEM device formed from, for example, a transition metal oxide may also preserve the “born on” property of a CEM device, which refers to a CEM device's ability to exhibit a relatively low impedance (relatively high conductivity) responsive to fabrication of the device.

FIGS. 3A-3D are illustrations depicting electron donation and back-donation via sigma and pi bonds of a metal-carbonyl molecule in a CEM according to an embodiment. As previously described, changes in impedance states of CEM devices, such a change from a low-impedance state to a high-impedance state, for example, may be brought about by donation/back-donation of electrons to and from a ligand and a metal atom, such as Ni. In particular embodiments, such as described with respect to FIGS. 3A-3D, electron donation, which occurs in a first direction, such as from a ligand molecule to a metal atom, may be achieved via a sigma bond, which may involve a higher (or even the highest) occupied molecular orbital of, for example, a carbonyl ligand in a CEM comprising NiO:CO. Electron back-donation, which occurs in a second direction, such as from a metal atom to a ligand molecule, may be achieved via a pi bond, which may represent the lowest unoccupied molecular orbital of, for example, a carbonyl ligand.

To illustrate electron donation/back-donation, embodiment 300 (FIG. 3A) represents a carbonyl (CO) molecule which may function, at least in particular embodiments, as a substitutional ligand of a CEM, such as a CEM comprising nickel oxide (NiO), to form NiO:CO, for example. In the embodiment of FIG. 3A, sigma bond 310 may represent a bonding electron orbital that allows one or more electrons to migrate from a CO ligand in a direction towards a metal ion of a CEM, such as, for example, NiO. In embodiment 320 (FIG. 3B), pi bonds 322 and 324 comprise antibonding orbitals representing the lowest unoccupied molecular orbital of a CO ligand, for example. For the particular instance of a CO ligand, pi bonds 322 and 324 may accept electrons from, for example, “d” orbitals of a metal atom, such as Ni.

In embodiment 340 (FIG. 3C), a metal atom, which may comprise, for example, Ni in a CEM comprising NiO:CO, is shown as accepting an electron from a sigma bond of a carbonyl ligand. In an embodiment, an electron accepted from a sigma bond of a carbonyl ligand may complement a “d” orbital of, for example, a Ni atom, which may place the atom into an oxidation state of 2+(e.g., Ni²⁺ in a material such as NiO:CO or NiO:NH₃). Accordingly, electron donation to bring about a transition to a relatively conductive state of a CEM device may be summarized substantially in accordance with expression (7), below:

Ni¹⁺+Ni³⁺→2Ni²⁺ (7)

In embodiment 360, (FIG. 3D), a metal atom, which may comprise, for example, Ni in a CEM comprising NiO:CO is shown as reversing a back-donating process in which electrons are back-donated from “d” orbitals 335 and 337 of a Ni atom (represented by M in FIGS. 3C and 3D). For the particular instance of a NiO:CO complex, as shown in FIG. 3D, electrons from the “d” orbital are donated to a lower (or even the lowest) unoccupied molecular orbital (pi bonds) of the CO molecule. As described with regard to expression (4) herein, back-donation may result in disproportionation, which may comprise simultaneous oxidation and reduction substantially in accordance with expression (8) (which is identical to expression (4)).

2Ni²⁺→Ni¹⁺+Ni³⁺ (8)

Such disproportionation, in this instance, refers to formation of nickel ions as Ni¹⁺+Ni³⁺ as shown in expression (8), which may bring about, for example, a relatively high-impedance state during operation of the CEM device.

FIG. 3E shows a representative NiO complex 380 comprising a defect in the form of an oxygen vacancy in a correlated electron material, which may be repaired by the carbonyl molecule of FIGS. 3A-3D, according to an embodiment. In particular embodiments, NiO complex 385 may represent a coordination sphere of Ni atoms 390 and 391. As previously noted, such defects, which may include oxygen vacancy 395, may bring about a degradation in electron donation and back-donation in a CEM material. In turn, a degradation in electron donation and back-donation in a CEM material may give rise to a decrease in conductivity of a CEM-based device, an increase in charge storage within a CEM-based device (which may increase parasitic capacitance and, consequently, decrease high-frequency switching performance), and/or may impact other performance aspects of a CEM-based device, and claimed subject matter is not limited in this respect.

Thus, in the embodiment FIG. 3E, a defect in NiO complex 385, such as oxygen vacancy 395, for example, may be repaired by CO ligand 397 or NH₃ ligand 398, which may operate as a substitutional ligand that may fill oxygen vacancy 395. CO ligand 397 or NH₃ ligand 398 may be introduced into a CEM film utilizing, for example, an annealing step in which a CEM film comprising NiO is exposed, in a chamber, to gaseous CO (or gaseous NH₃) at a temperature approximately in the range of 100° C. to 800° C., for example. In particular embodiments, a substitutional ligand, such as CO ligand 397 and NH₃ ligand 398, for example, may operate to adjust local electronegativity of a coordination sphere, which may promote electron donation/back-donation. Accordingly, a presence of substitutional ligands, such as CO ligand 397 and NH₃ ligand 398 on, for example, may operate to reduce concentration of defects in coordination spheres forming a CEM. In embodiments, reducing concentration of defects in coordination spheres that form a CEM, by way of promoting electron donation/back-donation, may give rise to increased conductivity, decreased capacitance, and/or bring about additional performance enhancements of a CEM-based device. Additionally, by way of promoting electron donation/back-donation, nanoionic filament formation, in which conductive filaments may form within a transition metal oxide film, may be inhibited from occurring.

FIGS. 4A-4B are graphs depicting energy versus density of states in a nickel-based CEM comprising oxygen as the dominant ligand according to an embodiment. In embodiment 400 (FIG. 4A), empty conduction band 410, which may be referred to as the upper Hubbard band, lies only slightly above the Fermi level. Valence band 420, which may be referred to as the lower Hubbard band, lies slightly below the Fermi level. The energy versus density of states graph of FIG. 4A, which indicates that electrons may move with relative ease between conduction and valence bands of a CEM, for example, corresponds to a CEM that may operate in a conductive (e.g., metallic) state. In a particular example, the energy versus density of states graph of FIG. 4A may correspond to a low impedance (conductive) state, in which electron donation/back-donation are prevalent. For the example of a CEM-based material comprising Ni, such as NiO, utilizing carbonyl and/or ammonia as substitutional ligands (NiO:CO and NiO:NH₃), the energy versus density of states graph of FIG. 4A may be indicative of a condition in which the “3d” orbitals of Ni atoms include 8 electrons and Ni comprises an oxidation number of 2+. This relationship may be summarized in expression (9) below:

2Ni²⁺=>3d⁸+3d⁸ (9)

Additionally, in particular embodiments, NiO may operate as a P-type CEM device, which may operate to drive the Fermi level downward in FIG. 4A, such as in the direction of valence band 420. In this context, a “P-type doped CEM” as referred to herein means a first type of CEM comprising a particular molecular dopant that exhibits increased electrical conductivity, relative to an undoped CEM, if the CEM is operated in a low-impedance state. Introduction of a substitutional ligand, such as CO and NH₃, may operate to enhance the P-type nature of a NiO CEM. Accordingly, an attribute of P-type operation of a CEM may include, at least in particular embodiments, an ability to tailor or customize electrical conductivity of a CEM, operated in a low-impedance state, by controlling an atomic concentration of a P-type dopant in a CEM. In particular embodiments, an increased atomic concentration of a P-type dopant may bring about increased electrical conductivity of a CEM, although claimed subject matter is not limited in this respect.

In embodiment 450 (FIG. 4B), a band-splitting potential (U), which, in certain embodiments, may represent a difference between ionization energy and electron affinity, separates conduction band 460 from valence band 470. Accordingly, the energy versus density of states graph of FIG. 4B, which indicates that electrons may be restricted from moving between conduction and valence bands of a CEM, corresponds to a CEM that may operate in a insulative (high-impedance) state. For the example of a CEM-based material comprising Ni, such as NiO, utilizing carbonyl and/or ammonia as substitutional ligands (NiO:CO and NiO:NH₃), the energy versus density of states graph of FIG. 4A may be indicative of a condition in which a first “3d” orbital of Ni atoms includes 7 electrons while a second “3d” orbital of Ni includes 9 electrons. In this example, oxidation numbers of adjacent Ni atoms of a coordination sphere, such as in NiO complex 385 of FIG. 3E, may not be equivalent to one another, such as N¹⁺ and Ni³⁺, for example, and Ni may comprise an oxidation number of 2+. This relationship may be summarized in expression (10) below:

Ni¹⁺+Ni³⁺=>3d⁷+3d⁹ (10)

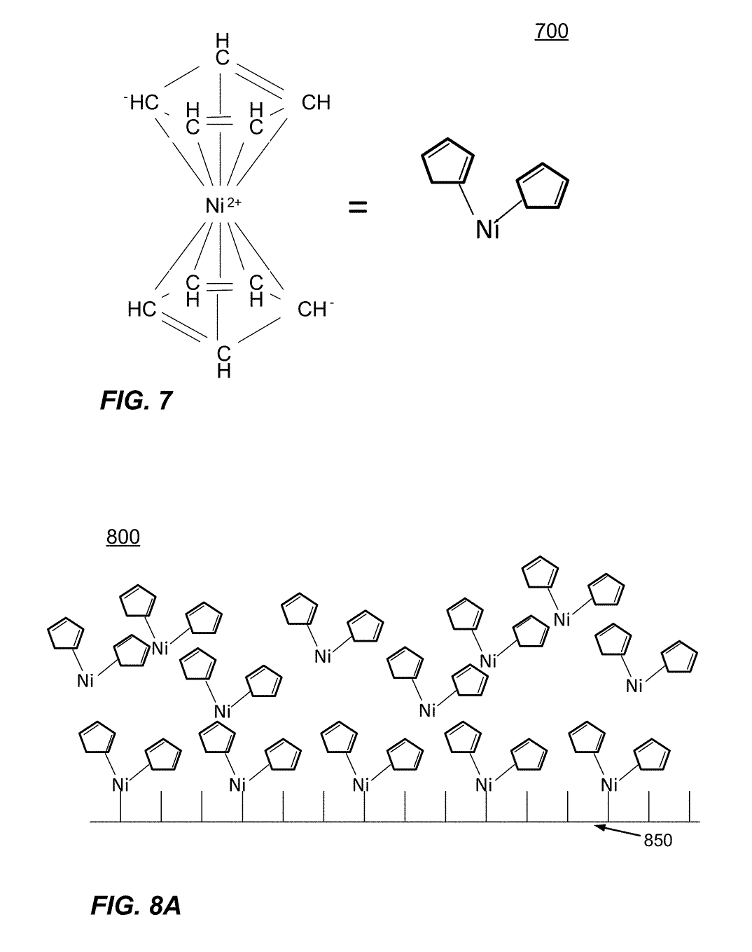

FIG. 5 is a flow diagram of an embodiment 500 for a process for fabricating a correlated electron material. Example implementations, such as described in FIG. 5, and other figures described herein, may include blocks in addition to those shown and described, fewer blocks, or blocks occurring in an order different than may be identified, or any combination thereof. The method may begin at block 510, which may comprise forming, in a chamber, one or more layers of CEM on a substrate. The one or more layers of the CEM may be formed from a transition metal and a dominant ligand. The one or more layers of CEM may have a concentration of defects in the coordinate spheres forming the CEM. The method may continue at block 520, which may comprise exposing the one or more layers of CEM to a molecular dopant comprising a substitutional ligand to form a P-type CEM. The substitutional ligand may operate to reduce the concentration of defects in the coordination spheres forming the CEM, wherein the reduction in the concentration of defects in the coordinate spheres inhibits conductive filament formation in the one or more layers of the CEM.

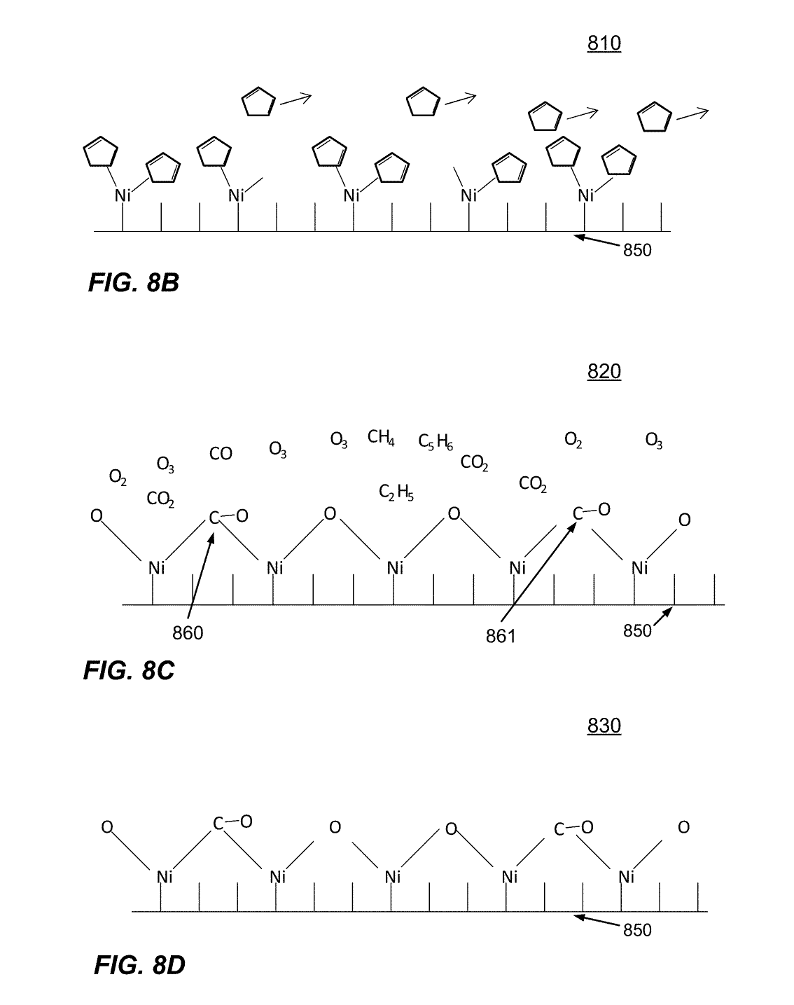

As previously described herein, a molecular dopant, such as carbonyl (CO), may permit sharing of electrons during operation of the CEM device so as to give rise to the disproportionation reaction of expression (4), and its reversal, substantially in accordance with expression (5). Accordingly, using carbonyl as a molecular dopant, FIG. 6A are flow diagrams of methods for fabricating correlated electron device materials according to an embodiment 601. Example implementations, such as described in FIGS. 6A, 6B, and 6C, for example, may include blocks in addition to those shown and described, fewer blocks, or blocks occurring in an order different than may be identified, or any combination thereof. In an embodiment, a method may include blocks 610, 630, and 650, for example. The method of FIG. 6A may accord with the general description of atomic layer deposition previously described herein. The method of FIG. 6A may begin at block 610, which may comprise exposing the substrate, in a heated chamber, for example, to a first precursor in a gaseous state (e.g., “AX”), wherein the first precursor comprises a transition metal oxide, a transition metal, a transition metal compound or any combination thereof, and a first ligand. In one example, as noted at block 610, nickel cyclopentadienyl (Ni(Cp)₂ may be utilized, where in Ni represents a transition metal and CP represents a ligand.

The method may continue at block 620, which may comprise removing the precursor AX and byproducts of AX by using an inert gas or evacuation or a combination thereof. The method may continue at block 630, which may comprise exposing the substrate to a second precursor (e.g., BY) in a gaseous state, wherein the second precursor comprises a oxide so as to form a first layer of the film of a CEM device. The method may continue at block 640, which may comprise removing the precursor BY and byproducts of BY through the use of an inert gas or evacuation or combination. The method may continue at block 650, which may comprise repeating the exposing of the substrate to the first and second precursors with intermediate purge and/or evacuation steps so as to form additional layers of the film until the correlated electron material may be capable of exhibiting a ratio of first to second impedance states of at least 5.0:1.0.

FIG. 6B is a flow diagram of a method for fabricating correlated electron device materials according to an embodiment 602. The method of FIG. 6B may accord with the general description of chemical vapor deposition or CVD or variations of CVD such as plasma enhanced CVD and others. In FIG. 6B, such as at block 660, a substrate may be exposed to precursor AX and BY simultaneously under conditions of pressure and temperature to promote the formation of AB, which corresponds to a CEM. Additional approaches may be employed to bring about formation of a CEM, such as application of direct or remote plasma, use of hot wire to partially decompose precursors, or lasers to enhance reactions as examples of forms of CVD. The CVD film processes and/or variations, may for a duration and under conditions as can be determined by one skilled in the art of CVD until, for example, correlated electron material having appropriate thickness and exhibiting appropriate properties, such as electrical properties, such as a ratio of first to second impedance states of at least 5.0:1.0.

FIG. 6C is a flow diagram of a method for fabricating correlated electron device materials according to an embodiment 603. The method of FIG. 6C may accord with the general description of physical vapor deposition or PVD or Sputter Vapor Deposition or variations of these and/or related methods. In FIG. 6C, at block 671, a substrate may be exposed in a chamber, for example, to an impinging stream of precursor having a “line of sight” under particular conditions of temperature and pressure to promote formation of a CEM comprising material AB. The source of the precursor may be, for example, AB or A and B from separate “targets” wherein deposition is brought about using a stream of atoms or molecules that are physically or thermally or by other means removed (sputtered) from a target comprised of material A or B or AB and are in “line of sight” of the substrate. In an implementation, a process chamber may be utilized wherein pressure within the process chamber pressure comprises a value low enough, such as a pressure value that approaches a lower threshold, or a pressure value lower than a threshold, such that the mean free path of the atoms or molecules or A or B or AB is approximately or more than the distance from the target to the substrate. The stream of AB (or A or B) or both may combine to form AB on the substrate due to conditions of the reaction chamber pressure, temperature of the substrate and other properties that are controlled by one skilled in the art of PVD and sputter deposition. In other embodiments of PVD or sputter deposition, the ambient environment may be a source such as BY or for example an ambient of O₂ for the reaction of sputtered nickel to form NiO doped with carbon or CO, for example co-sputtered carbon. The PVD film and its variations may continue for a time required and under conditions as can be determined by one skilled in the art of PVD until correlated electron material of thickness and properties is deposited that is capable of exhibiting a ratio of first to second impedance states of at least 5.0:1.0.

The method may continue at block 672 in which, at least some embodiments, a metal, such as nickel, may be sputtered from a target and a transition metal oxide may be formed in a subsequent oxidation process. The method may continue at block 673 in which, at least in some embodiments, a metal or metal oxide may be sputtered in a chamber comprising gaseous carbon with or without a substantial portion of oxygen.

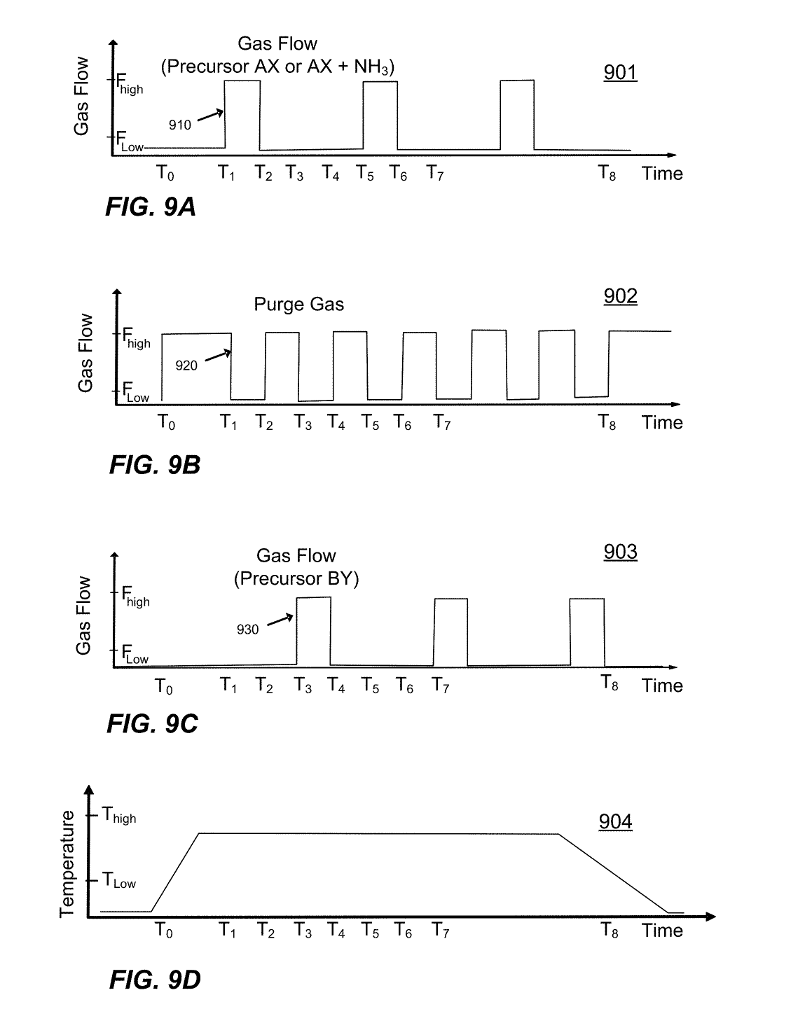

As noted above, with regard to block 610 of FIG. 6A, Ni(Cp)₂ is indicated as one possible example of a transition metal and ligand utilized in the formation of a CEM film. Thus, FIG. 7 provides a diagram of a Bis(cyclopentadienyl) molecule (Ni(C₅H₅)₂), which may function as an example precursor, in a gaseous form, utilized in fabrication of correlated electron material devices according to an embodiment. In embodiments, Ni(C₅H₅)₂ may function as a precursor, in a gaseous form, utilized in fabrication of correlated electron materials according to an embodiment 700. As shown in FIG. 7, a nickel atom, near the center of the nickel dicyclopentadienyl molecule, has been placed in an ionization state of +2 to form an Ni²⁺ ion. In the example molecule of FIG. 7, an additional electron is present in the upper left and lower right CH⁻ sites of the cyclopentadienyl (Cp) portions of the dicyclopentadienyl ((Cp)₂) molecule. FIG. 7 additionally illustrates a shorthand notation showing nickel bonded to pentagon-shaped monomers of a dicyclopentadienyl molecule.

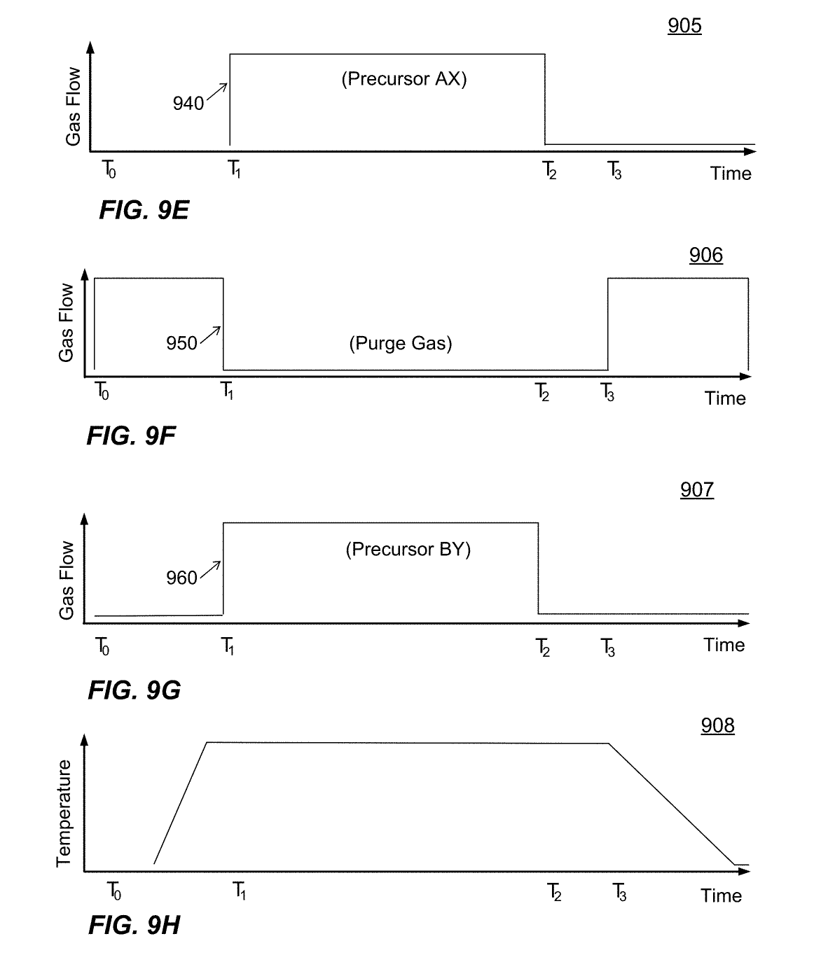

FIGS. 8A-8D show sub-processes utilized in a method for fabricating a NiO-based film comprising a CEM according to an embodiment. The sub-processes of FIGS. 8A-8D may correspond to the atomic layer deposition process utilizing precursors AX and BY of expression (6) to deposit components of NiO:CO onto a conductive substrate. In embodiments, a conductive substrate may comprise an electrode material comprising materials similar to those utilized in the construction of conductive substrate 210, as described with respect to FIG. 2 herein. However, the sub-processes of FIGS. 8A-8D may be utilized, with appropriate material substitutions, to fabricate films comprising CEM that utilize other transition metals, transition metal oxides, transition metal compounds or combinations thereof, and claimed subject matter is not limited in this respect.

As shown in FIG. 8A, (embodiment 800) a substrate, such as substrate 850, may be exposed to a first gaseous precursor, such as precursor AX of expression (6a), such as a gaseous precursor comprising nickel dicyclopentadienyl (Ni(Cp)₂) for a duration of approximately in the range of 0.5 seconds to 180.0 seconds. As previously described, concentration, such as atomic concentration, of a first gaseous precursor, as well as exposure time, may be adjusted so as to bring about a final atomic concentration of carbon, such as in the form of carbonyl, of between approximately 0.1% and 10.0%, for example. As shown in FIG. 8A, exposure of a substrate to gaseous (Ni(Cp)₂ may result in attachment of (Ni(Cp)₂) molecules or (Ni(Cp) at various locations of the surface of substrate 850. Deposition may take place in a heated chamber, which may attain, for example, a temperature approximately in the range of 20.0° C. to 400.0° C. However, it should be noted that additional temperature ranges, such as temperature ranges comprising less than approximately 20.0° C. and greater than approximately 400.0° C. are possible, and claimed subject matter is not limited in this respect.

As shown in FIG. 8B, (embodiment 810) after exposure of a conductive substrate, such as conductive substrate 850, to a gaseous precursor, such as a gaseous precursor comprising (Ni(Cp)₂), the chamber may be purged of remaining gaseous Ni(Cp)₂ and/or Cp ligands. In an embodiment, for the example of a gaseous precursor comprising (Ni(Cp)₂), the chamber may be purged for duration approximately in the range of 0.5 seconds to 180.0 seconds. In one or more embodiments, a purge duration may depend, for example, on affinity (aside from chemical bonding) of unreacted ligands and byproducts with a transition metal, transition metal compounds, transition metal oxide, or the like surface as well as other surfaces present in the process chamber. Thus, for the example of FIG. 8B, if unreacted Ni(Cp)₂, Ni(Cp),Ni, and other byproducts were to exhibit an increased affinity for the surfaces of the substrate or chamber, a larger purge duration may be utilized to remove remaining gaseous ligands, such as those mentioned. In other embodiments, purge duration may depend, for example, on gas flow within the chamber. For example, gas flow within a chamber that is predominantly laminar may permit removal of remaining gaseous ligands at a faster rate, while gas flow within a chamber that is predominantly turbulent may permit removal of remaining ligands at a slower rate. It should be noted that claimed subject matter is intended to embrace purging of remaining gaseous material without regard to flow characteristics within a chamber.

As shown in FIG. 8C, (embodiment 820) a second gaseous precursor, such as precursor BY of expression (6a), may be introduced into the chamber. As previously mentioned, a second gaseous precursor may comprise an oxidizer, which may operate to displace a first ligand, such as (Cp)₂, for example, and replace the ligand with an oxidizer, such as oxygen (O₂), ozone (O₃), nitric oxide (NO), hydrogen peroxide (H₂O₂), just to name a few examples. Accordingly, as shown in FIG. 8C, oxygen atoms may form bonds with at least some nickel atoms bonded to substrate 850. In an embodiment, precursor BY may oxidize (Ni(Cp)₂) to form a number of additional oxidizers, and/or combinations thereof, in accordance with expression (11) below:

Ni(C₅H₅)₂+O₃→NiO+potential byproducts (e.g., CO, CO₂, C₅H₅, C₅H₆, CH₃, CH₄, C₂H₅, C₂H₆, . . . ) (11)

Wherein C₅H₅ has been substituted for Cp in expression (11). As shown in FIG. 8C, a number of potential byproducts are shown, including C₂H₅, CO₂, CH₄, and C₅H₆. As is also shown in FIG. 8C, carbonyl (CO) molecules may bond to nickel oxide complexes, such as at sites 860 and 861, for example. In embodiments, such nickel-to-carbonyl bonds (e.g. NiO:CO), in an atomic concentration of between, for example, 0.1% and 10.0%, may bring about the substantially rapid conductor/insulator transition of a CEM device.

As shown in FIG. 8D, (embodiment 830) potential hydrocarbon byproducts, such as CO, CO₂, C₅H₅, C₅H₆, CH₃, CH₄, C₂H₅, C₂H₆, for example, may be purged from the chamber. In particular embodiments, such purging of the chamber may occur for a duration approximately in the range of 0.5 seconds to 180.0 seconds utilizing a pressure approximately in the range of 0.01 Pa to 105.0 kPa.

In particular embodiments, the sub-processes described shown in FIGS. 8A-8D may be repeated until a desired thickness, such as a thickness approximately in the range of 1.5 nm to 100.0 nm, is achieved. As previously mentioned herein, atomic layer deposition approaches, such as shown and described with reference to FIGS. 8A-8D, for example, may give rise to a CEM device film having a thickness approximately in the range of 0.6 Å to 1.5 Å for one ALD cycle, for example. Accordingly, to construct a CEM device film comprising a thickness of 500.0 Å (50.0 nm), just as a possible example, approximately 300 to 900 two-precursor cycles, utilizing AX+BY for example, may be performed. In certain embodiments, cycles may be occasionally interspersed among differing transition metals, and/or transition metal compounds and/or transition metal oxides to obtain desired properties. For example, in an embodiment, two atomic layer deposition cycles, in which layers of NiO:CO may be formed, may be followed by three atomic layer deposition cycles to form, for example, titanium oxide carbonyl complexes (TiO:CO). Other interspersing of transition metals, and/or transition metal compounds and/or transition metal oxides is possible, and claimed subject matter is not limited in this respect.

In particular embodiments, after the completion of one or more atomic layer deposition cycles, a substrate may be annealed, which may assist in controlling grain structure, densifying the CEM film or otherwise improving the film properties, performance or endurance. For example, if atomic layer deposition produces the number of columnar shaped grains, annealing may permit boundaries of columnar-shaped grains to grow together which may, for example, reduce resistance variations of the CEM device, for example. Annealing may give rise to additional benefits, such as more evenly distributing of carbon molecules, such as carbonyl; for example, throughout the CEM device material, and claimed subject matter is not limited in this respect.

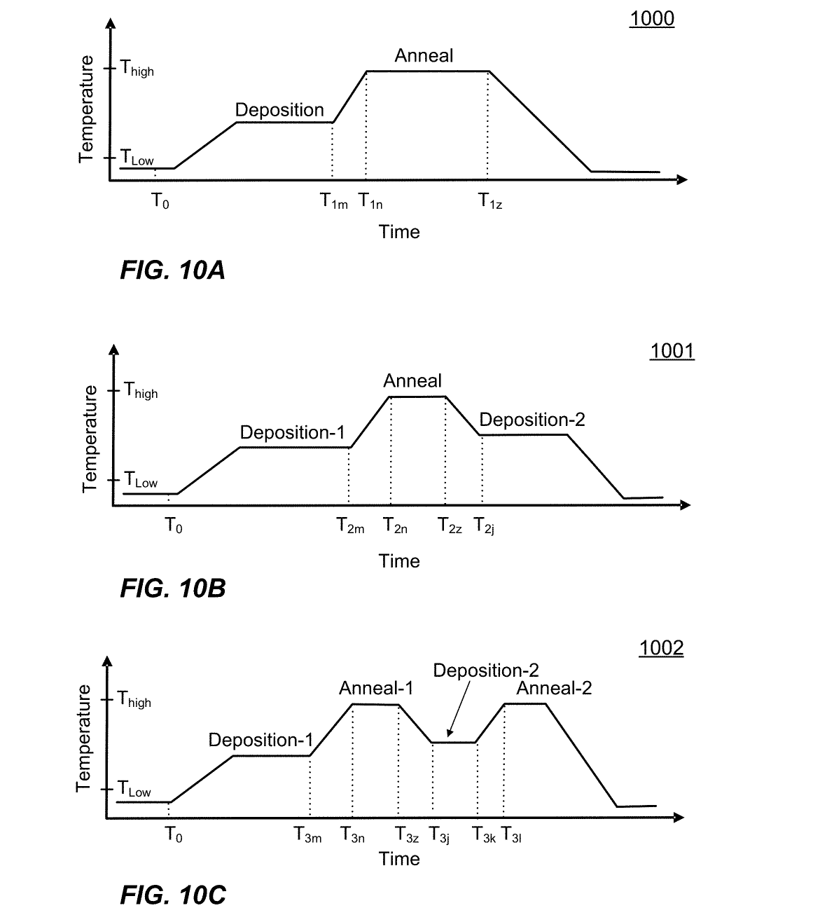

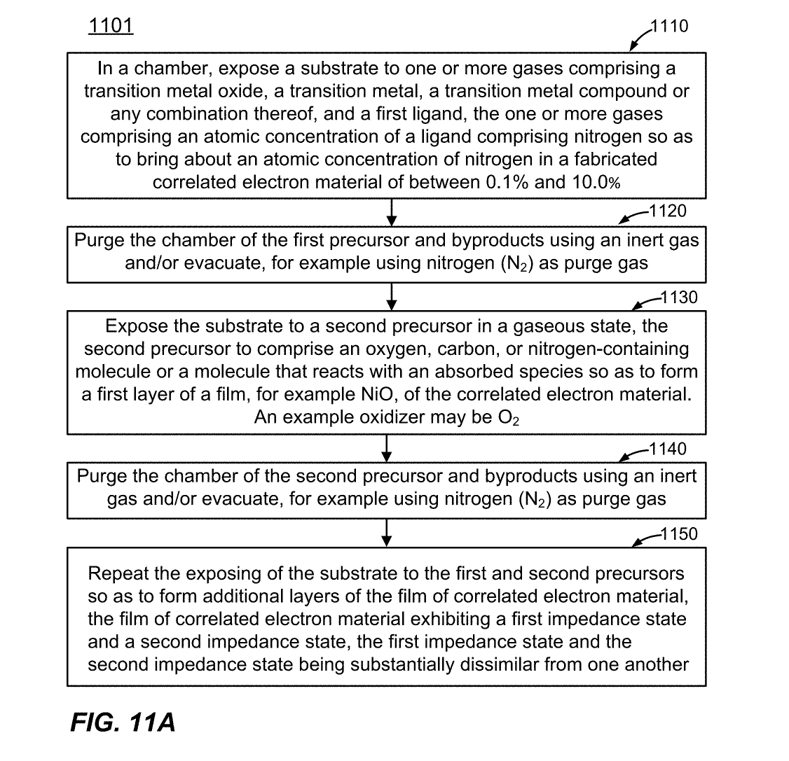

FIGS. 9A-9D are diagrams showing precursor flow and temperature profiles, as a function of time, which may be used in a method for fabricating CEM device, such as an NiO-based device, according to an embodiment. A common timescale (T₀-T₈) is utilized for FIGS. 9A-9D. FIG. 9A shows a precursor gas flow profile 910 for a precursor (e.g., AX), according to an embodiment 901. As shown in FIG. 9B, precursor gas flow may be increased, so as to permit the precursor gas to enter a chamber within which a CEM device is undergoing fabrication. Thus, in accordance with precursor gas flow profile 910, at time T₀, precursor AX gas flow may be approximately 0.0 (e.g. negligible). At time T₁, precursor AX gas flow may be increased to relatively higher value. At time T₂, which may correspond to a time approximately in the range of 0.5 seconds to 180.0 seconds after time T₁, precursor AX gas may be purged and/or evacuated from the chamber, such as by purging, for example. Precursor AX gas flow may be stopped until approximately time T₅, at which time precursor AX gas flow may be increased to a relatively higher value. After time T₅, such as at times T₆ and T₇ precursor AX gas flow may be returned to 0.0 (e.g. negligible amount) until increased at a later time.

FIG. 9B shows a gas flow profile 920 for a purge gas, according to an embodiment 902. As shown in FIG. 9B, purge gas flow may be increased and decreased so as to permit evacuation of the fabrication chamber of precursor gases AX and BY, for example. At time T₀, purge gas profile 920 indicates a relatively high purge gas flow, which may permit removal of impurity gases within the fabrication chamber prior to time T₁. At time T₁, purge gas flow may be reduced to approximately 0.0, which may permit introduction of precursor AX gas into the fabrication chamber. At time T₂, purge gas flow may be increased for duration of approximately in the range of 0.5 seconds to 180.0 seconds so as to permit removal of excess precursor gas AY and reaction byproducts from the fabrication chamber.

FIG. 9C shows a gas flow profile 930 for a precursor gas (e.g., BY), according to an embodiment 903. As shown in FIG. 9C, precursor BY gas flow may remain at a flow of approximately 0.0, until approximately time T₃, at which gas flow may be increased to relatively higher value. At time T₄, which may correspond to a time approximately in the range of 0.5 seconds to 180.0 seconds after time T₂, precursor BY gas may be purged and/or evacuated from the chamber, such as by purging, for example. Precursor BY gas flow may be returned to 0.0, until approximately time T₇, at which time precursor BY gas flow may be increased to a relatively higher value.

At time T₃, purge gas flow may be decreased to relatively low value, which may permit precursor BY gas to enter the fabrication chamber. After exposure of the substrate to precursor BY gas, purge gas flow may again be increased so as to permit removal of the fabrication chamber of precursor BY gas, which may signify completion of a single atomic layer of a CEM device film, for example. After removal of precursor BY gas, precursor AX gas may be reintroduced to the fabrication chamber so as to initiate a deposition cycle of a second atomic layer of a CEM device film. In particular embodiments, the above-described process of introduction of precursor AX gas into the fabrication chamber, purging of remaining precursor AX gas from the fabrication chamber, introduction of precursor BY gas, and purging of remaining precursor BY gas, may be repeated, for example, approximately in the range of 300 times to 900 times, for example. Repetition of the above-described process may bring about CEM device films having a thickness dimension of, for example, between approximately 20.0 nm and 100.0 nm, for example.

FIG. 9D is a diagram showing a temperature profile, as a function of time, used in a method for fabricating correlated electron device materials according to an embodiment 904. In FIG. 9D, a deposition temperature may be raised to attain a temperature of, for example, a temperature approximately in the range of 20.0° C. to 900.0° C. However, in particular embodiments, somewhat smaller ranges may be utilized, such as temperature ranges approximately in the range of 100.0° C. to 800.0° C. Further, for particular materials, even smaller temperature ranges may be utilized, such as from approximately 100.0° C. to approximately 600.0° C.

FIGS. 9E-9H are diagrams showing precursor flow and temperature profiles, as a function of time, which may be used in a method for fabricating correlated electron device materials according to an embodiment. A common timescale (T₀-T₃) is utilized for FIGS. 9E-9H. As shown in 905, precursor AX may be brought into a fabrication chamber at time T₁, where time T₀ to time T₁ is used to purge and/or evacuate the process chamber in preparation for the deposition by an increase in purge gas flow such as shown in embodiment 950. Embodiment 940 shows a relative increase in flow of precursor AX that occurs at time T₁. Also at time T₁, flow of a second reactant precursor, BY, may be increased as shown in embodiment 907 with gas flow increase at 960. The two precursors (AX and BY) may flow substantially at the same time for the amount of time required for the thickness of the CEM film. The temperature profile shown in FIG. 9H (embodiment 908) shows the temperature for deposition is set before or near the time, T₀.

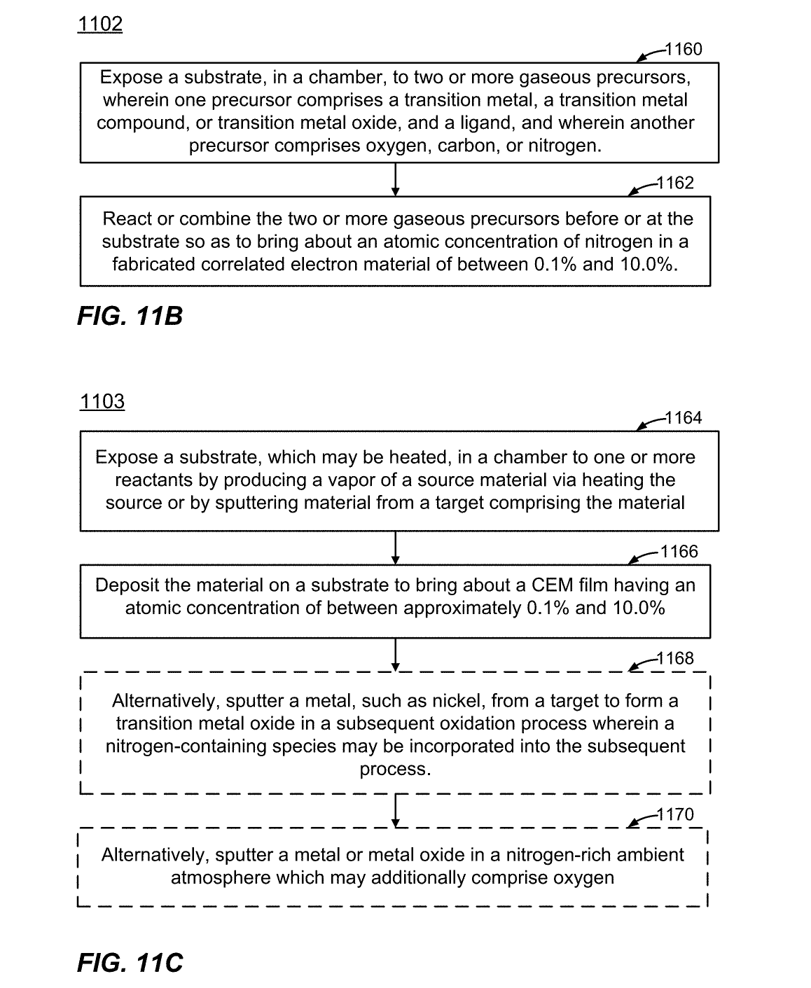

FIGS. 10A-10C are diagrams showing temperature profiles, as a function of time, used in deposition and annealing processes for fabricating CEM devices according to an embodiment. As shown in FIG. 10A (embodiment 1000), deposition may take place during an initial time span, such as from T₀ to T₁ₘ, during which time, a CEM device film may be deposited upon an appropriate substrate utilizing an atomic layer deposition process. After deposition of a CEM device film, an annealing period may follow. In some embodiments, a number of atomic layer deposition cycles may range from, for example, approximately 10 cycles, to as many as 1000 cycles or more, and claimed subject matter is not limited in this respect. After completion of deposition of a CEM film onto a suitable substrate, relatively high-temperature annealing or an annealing at the same temperature or lower temperature than the deposition temperature may be performed utilizing a temperature approximately in the range of 20.0° C. (T_{low}) to 900.0° C., (T_{high}) such as from time Tₗₙ to time T_{lz}. However, in particular embodiments, smaller ranges may be utilized, such as temperature ranges approximately in the range of 100.0° C. (T_{low}) to 800.0° C. (T_{high}). Further, for particular materials, even smaller temperature ranges may be utilized, such as from approximately 200.0° C. (Tim) to approximately 600.0° C. (T_{high}). Annealing times may range from approximately 1.0 second to approximately 5.0 hours, but may be narrowed to, for example, durations of approximately 0.5 minutes to 180.0 minutes. It should be noted that claimed subject matter is not limited to any particular temperature ranges for annealing of CEM devices, nor is claimed subject matter limited to any particular durations of annealing. In other embodiments the deposition method may be chemical vapor deposition, physical vapor deposition, sputter, plasma enhanced chemical vapor deposition or other methods of deposition or combinations of deposition methods such as a combination of ALD and CVD in order to form the CEM film.

In embodiments, annealing may be performed in a gaseous environment comprising one or more of gaseous nitrogen (N₂), hydrogen (H₂), oxygen (O₂), water or steam (H₂O), nitric oxide (NO), nitrous oxide (N₂O), nitrogen dioxide (NO₂), ozone (O₃), argon (Ar), helium (He), ammonia (NH₃), carbon monoxide (CO), methane (CH₄), acetylene (C₂H₂), ethane (C₂H₆), propane (C₃H₈), ethylene (C₂H₄), butane (C₄H₁₀), or any combination thereof. Annealing may also occur in reduced pressure environments or pressures up to and excess of atmospheric pressure, including pressures of multiple atmospheres.

As shown in FIG. 10B (embodiment 1001), deposition may take place during an initial time span, such as from T₀ to T₂ₘ (Deposition-1), during which between approximately 10 and approximately 500 cycles of atomic layer deposition may be performed. At time T₂ₙ, an annealing period may be initiated and may continue until time T_{2z}. After time T_{2z}, a second set of atomic layer deposition cycles may occur, perhaps numbering between approximately 10 and approximately 500 cycles, for example. As shown in FIG. 10B, a second set of atomic layer deposition (Deposition-2) cycles may occur. In other embodiments the deposition method may be chemical vapor deposition, physical vapor deposition, sputter, plasma enhanced chemical vapor deposition or other methods of deposition or combinations of deposition methods such as a combination of ALD and CVD in order to form the CEM film.

As shown in FIG. 10C, (embodiment 1002) deposition may take place during an initial time span, such as from time T₀ to time Tam, during which between approximately 10 and approximately 500 cycles of atomic layer deposition may be performed. At time Tan, a first annealing period (Anneal-1) may be initiated and may continue until time T_{3z}. At time T₃ⱼ a second set of atomic layer deposition cycles (Deposition-2) may be performed until time T₃ₖ, at which a chamber temperature may be increased so that a second annealing period (Anneal-2) may occur, such as beginning at time T₃₁, for example. In other embodiments the deposition method may be chemical vapor deposition, physical vapor deposition, sputter, plasma enhanced chemical vapor deposition or other methods of deposition or combinations of deposition methods such as a combination of ALD and CVD in order to form the CEM film.

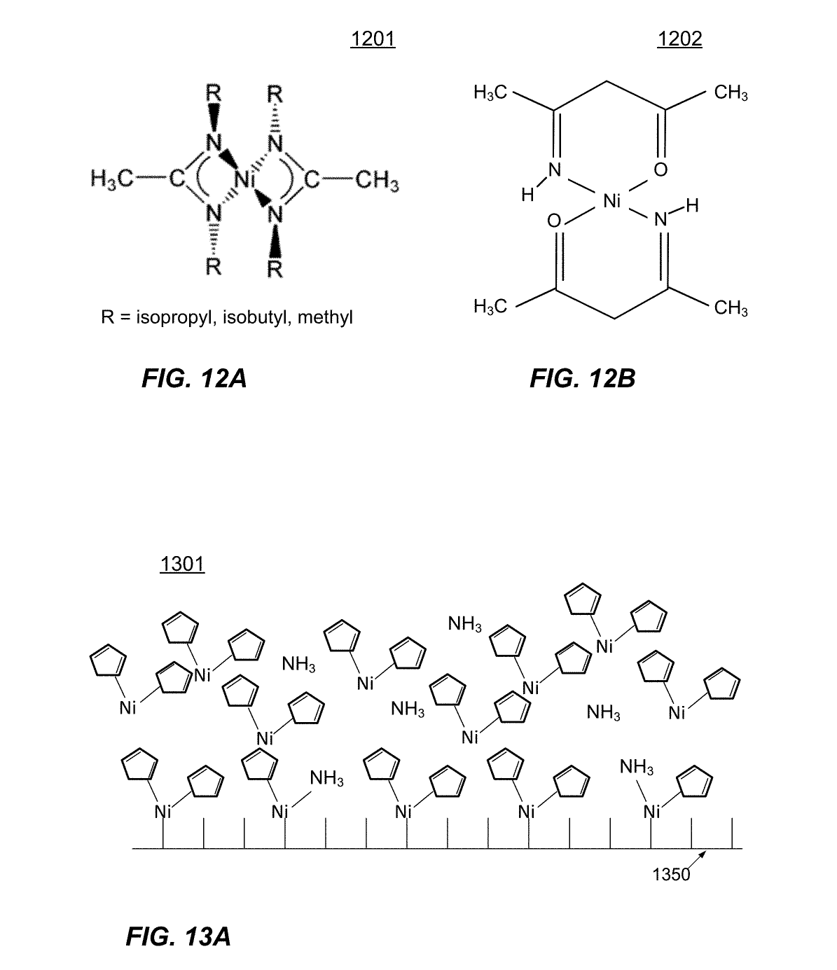

As previously described herein, a molecular dopant, such as such as a nitrogen-containing molecules (e.g., ammonia, cyano (CN⁻), azide ion(N₃⁻) ethylene diamine (C₂H₈N₂), phen(1,10-phenanthroline, and so forth) may permit sharing of electrons during operation of the CEM device so as to give rise to the disproportionation reaction of expression (4), and its reversal, substantially in accordance with expression (5). FIGS. 11A-11C are flow diagrams of methods for fabricating correlated electron material films using nitrogen-containing molecules according to one or more embodiments. Example implementations, such as described in FIGS. 11A, 11B, and 11C, for example, may include blocks in addition to those shown and described, fewer blocks, or blocks occurring in an order different than may be identified, or any combination thereof. In an embodiment, a method may include blocks 1110, 1120, 1130, 1140 and 1150, for example. The method of FIG. 11A (embodiment 1101) may accord with the general description of atomic layer deposition previously described herein. The method of FIG. 11A may begin at block 1110, which may comprise exposing the substrate, in a heated chamber, for example, to a first precursor in a gaseous state (e.g., “AX”), wherein the first precursor comprises a transition metal oxide, a transition metal, a transition metal compound or any combination thereof, and a first ligand (the ligand need not comprise a nitrogen dopant source). Examples of nitrogen-containing ligands for nickel precursors include nickel-amides, nickel-imides, and nickel-amidinates (Ni(AMD)). The method may continue at block 1120, which may comprise removing the excess precursor AX and byproducts of AX by using an inert gas or evacuation or combination. The method may continue at block 1130, which may comprise exposing the substrate to a second precursor (e.g., BY) in a gaseous state, wherein the second precursor comprises an oxide and/or may contain a nitrogen-based precursor (such as ammonia (NH₃), ethylene diamine (C₂H₈N₂), or members of a nitrogen oxide family (NA), such as nitric oxide (NO), nitrous oxide (N₂O), nitrogen dioxide (NO₂), or precursors with an NO₃⁻ ligand) so as to form a first layer of the film of a CEM device. The method may continue at block 1140, which may comprise removing the excess precursor BY and byproducts of BY through the use of an inert gas or by way of evacuation or by way of a combination of evacuation of the process chamber and purging of the chamber using an inert gas. The method may continue at block 1150, which may comprise repeating the exposing of the substrate to the first and second precursors with intermediate purge and/or evacuation steps so as to form additional layers of the film until the correlated electron material is capable of exhibiting a ratio of first to second impedance states of at least 5.0:1.0.

FIG. 11B is a flow diagram of a method for fabricating correlated electron device materials using nitrogen-containing molecules according to an embodiment 1102. The method of FIG. 11B may accord with the general description of chemical vapor deposition or CVD or variations of CVD such as plasma enhanced CVD and others. In FIG. 11B, such as at block 1160, a substrate may be exposed to precursor AX and BY simultaneously under conditions of pressure and temperature to promote the formation of AB, which corresponds to a CEM. Additional approaches may be employed to bring about formation of a CEM, such as application of direct or remote plasma, use of hot wire to partially decompose precursors, or lasers to enhance reactions as examples of forms of CVD. The CVD film processes and/or variations may occur for a duration and under conditions as can be determined by one skilled in the art of CVD until, for example, correlated electron material having appropriate thickness and exhibiting appropriate properties, such as electrical properties, such as a ratio of first to second impedance states of at least 5.0:1.0.

FIG. 11C is a flow diagram of a method for fabricating correlated electron device materials using nitrogen-containing molecules according to an embodiment 1103. The method of FIG. 11C may accord with the general description of physical vapor deposition or PVD or Sputter Vapor Deposition or variations of these and/or related methods. In FIG. 11C a substrate may be exposed in a chamber, for example, to an impinging stream of precursor having a “line of sight” under particular conditions of temperature and pressure to promote formation of a CEM comprising material AB. The source of the precursor may be, for example, AB or A and B from separate “targets” wherein deposition is brought about using a stream of atoms or molecules that are physically or thermally or by other means removed (sputtered) from a target comprised of material A or B or AB and are in “line of sight” of the substrate in a process chamber whose pressure is low enough or lower such that the mean free path of the atoms or molecules or A or B or AB is approximately or more than the distance from the target to the substrate. The stream of AB (or A or B) or both may combine to form AB on the substrate due to conditions of the reaction chamber pressure, temperature of the substrate and other properties that are controlled by one skilled in the art of PVD and sputter deposition. In other embodiments of PVD or sputter deposition, the ambient environment may be a source such as BY or for example an ambient of NH₃ for the reaction of sputtered nickel to form NiO doped with a nitrogen species such as NH₃. The PVD film and its variations will continue for a time required and under conditions as can be determined by one skilled in the art of PVD until correlated electron material of thickness and properties is deposited that is capable of exhibiting a ratio of first to second impedance states of at least 5.0:1.0.

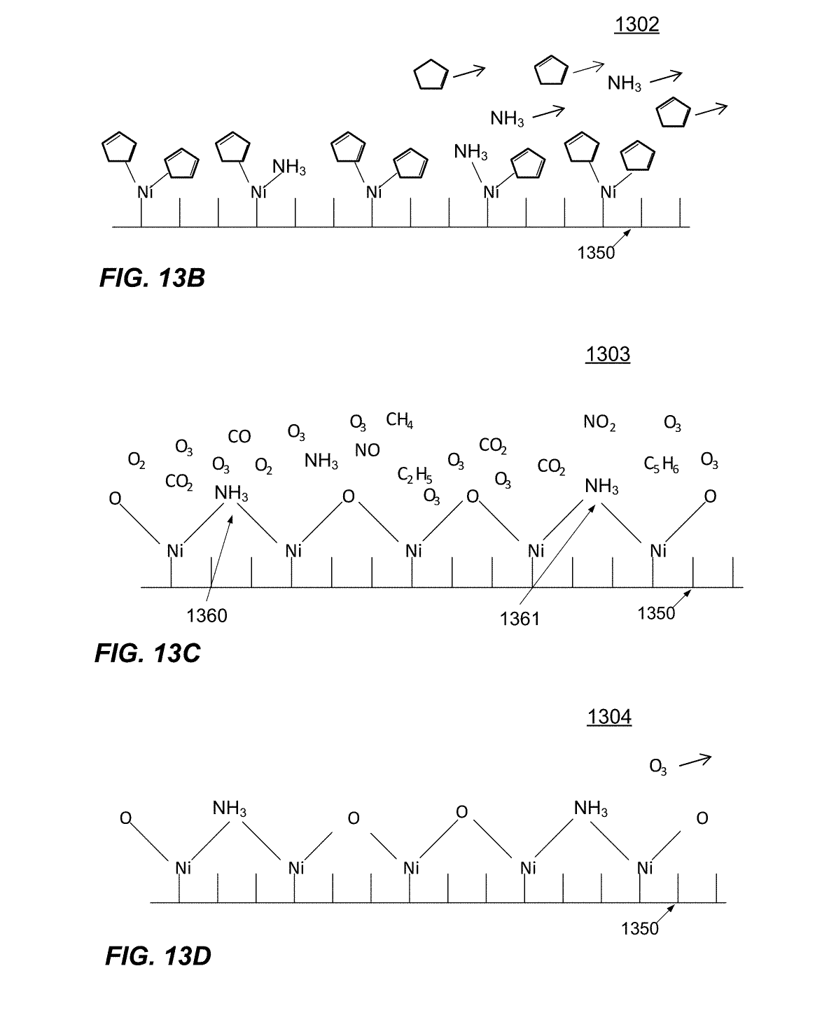

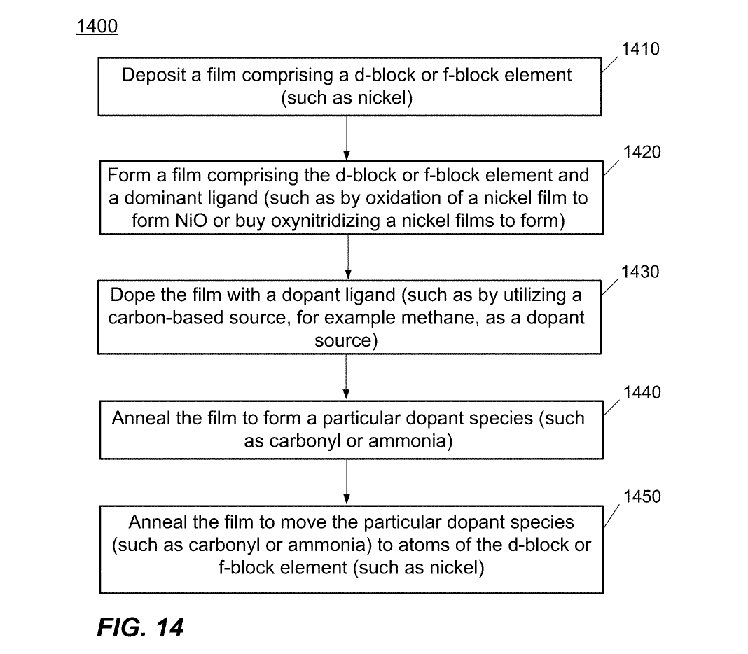

In embodiments, a single nitrogen containing precursor, such as shown in the example molecule of FIG. 12A, may be utilized in place of a mixture of gaseous precursors, such as AX and a nitrogen-based gas, to fabricate correlated electron material devices. FIG. 12A is a diagram of nickel amidinate Ni(AMD), which may function as a precursor to be utilized in fabrication of correlated electron material devices according to an embodiment 1201. As shown in FIG. 12A, a nickel atom, near the center of the (Ni(AMD)) molecule, is surrounded by four nitrogen atoms, one or more of which may attach to a hydrocarbon group (represented by “R” in FIG. 12A). Suitable hydrocarbon groups may include, but are not limited to an isopropyl group (C₃H₇), an isobutyl group (C₄H₉), or a methyl group (CH₃), just to name a few examples. In certain embodiments, (Ni(AMD)) may be utilized as precursor AX, thereby avoiding the need to utilize AX and a separate nitrogen-based gas, such as ammonia. In particular embodiments, oxidation, such as may occur responsive to exposure to precursor BY, for example, may release nitrogen atoms to permit their function as an electron donating/back-donating material.

In another embodiment, a nitrogen containing precursor, such as shown in the example molecule of FIG. 12B, may be utilized in place of a mixture of gaseous precursors, such as AX and a nitrogen-based gas, in the fabrication of correlated electron material devices. For example, as shown in the example molecule of FIG. 12B (embodiment 1202) nickel 2-amino-pent-2-en-4-onato (Ni(apo)₂) may be utilized as precursor AX, thereby avoiding the need to utilize AX and a separate nitrogen-based gas, such as ammonia. As shown in the example molecule of FIG. 12B (embodiment 1202), nitrogen may be supplied by the two nitrogen atoms positioned near the center of the Ni(apo)₂ molecule. In particular embodiments, oxidation, such as may occur responsive to exposure to precursor BY, for example, may release nitrogen atoms to permit their function as an electron donating/back-donating material.

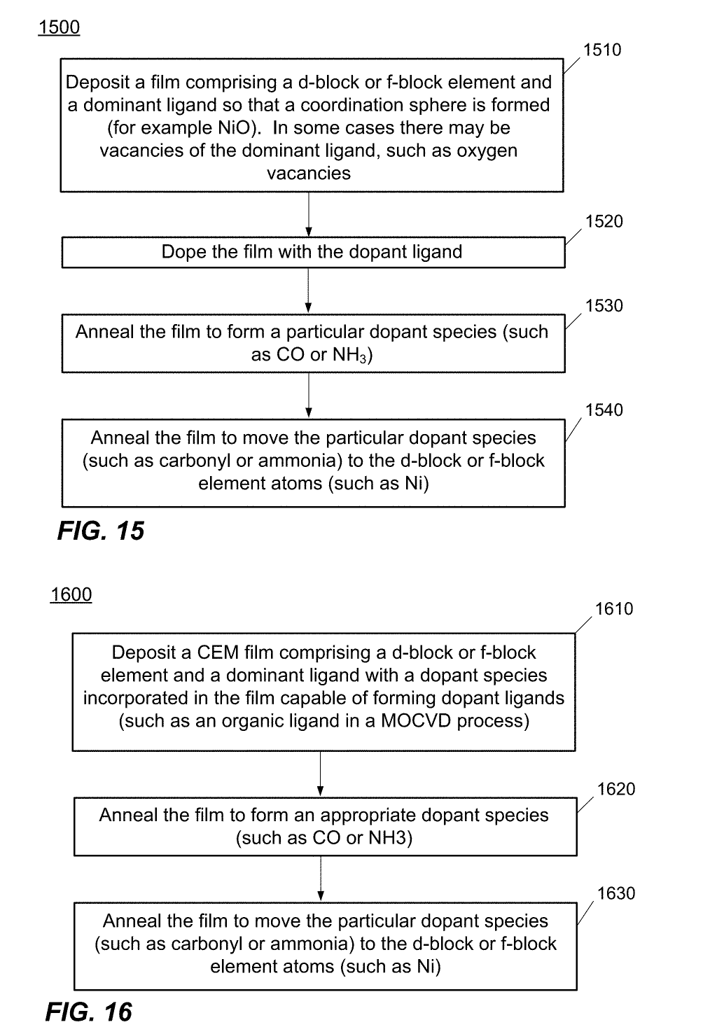

FIGS. 13A-13D show sub-processes utilized in a method for fabricating a film comprising a CEM according to an embodiment. The sub-processes of FIGS. 13A-13D may correspond to the atomic layer deposition process utilizing precursors AX, BY, and a nitrogen-based gas (such as ammonia (NH₃), ethylene diamine (C₂H₈N₂), and so forth) of expression (6b) to deposit components of NiO:NH₃ onto a conductive substrate. However, the sub-processes of FIGS. 13A-13D may be utilized, with appropriate material substitutions, to fabricate films comprising CEM that utilize other transition metals, transition metal compounds, transition metal oxides, or combinations thereof, and claimed subject matter is not limited in this respect.

As shown in FIG. 13A, (embodiment 1301) a substrate, such as substrate 1350, may be exposed to a first gaseous precursor, such as precursor AX of expression (6a), which may comprise of gaseous nickel dicyclopentadienyl (Ni(Cp)₂), gaseous nickel amidinate (Ni(AMD)), and/or gaseous nickel 2-amino-pent-2-en-4-onato, for example, for a duration of approximately in the range of 1.0 seconds to 120.0 seconds. In an embodiment that accords with expression (6b), precursor AX may be accompanied by a nitrogen-containing precursor, such as ammonia (NH₃), ethylene diamine (C₂H₈N₂), or other nitrogen-containing ligand. As previously described, atomic concentration of a first gaseous precursor, as well as exposure time, may be adjusted so as to bring about a final atomic concentration of nitrogen in a fabricated correlated electron material of between approximately 0.1% and 10.0%, for example.

As shown in FIG. 13A, exposure of a substrate to a mixture of gaseous nickel dicyclopentadienyl (Ni(Cp)₂), for example, and gaseous ammonia (NH₃), may result in attachment of (Ni(Cp)₂) molecules at various locations of the surface of substrate 1350. In embodiments, such attachment or deposition of Ni(Cp)₂ as well as ammonia (NH₃) may take place in a heated chamber, which may attain, for example, a temperature approximately in the range of 20.0° C. to 400.0° C. However, it should be noted that additional temperature ranges, such as temperature ranges comprising less than approximately 20.0° C. and greater than approximately 400.0° C. are possible, and claimed subject matter is not limited in this respect. It should be noted that gaseous precursors comprising (Ni(AMD)) (example molecule shown in FIG. 12A) and/or Ni(apo)₂ (example molecule shown in FIG. 12B) may be utilized in place of a mixture of gaseous of Ni(Cp)₂ and gaseous ammonia (NH₃).

As shown in FIG. 13B, (embodiment 1302) after exposure of a conductive substrate, such as conductive substrate 1350, to gaseous precursors, such as a mixture of gaseous precursors comprising (Ni(Cp)₂) and ammonia (NH₃), the chamber may be purged of remaining gaseous Ni(Cp)₂, Cp ligands, and unattached ammonia molecules. In an embodiment, for the example of a gaseous precursor comprising a gaseous mixture of Ni(Cp)₂) and NH₃, the chamber may be purged for duration approximately in the range of 5.0 seconds to 180.0 seconds. In one or more embodiments, a purge duration may depend, for example, on affinity (aside from chemical bonding) of unreacted ligands and/or unreacted ammonia molecules with a transition metal, a transition metal oxide, or the like. Thus, for the example of FIG. 13B, if unreacted (Cp)₂ and/or unreacted ammonia molecules were to exhibit an increased affinity for Ni, a larger purge duration may be utilized to remove remaining gaseous ligands, such as Cp ligands, as well as to remove unreacted ammonia. In other embodiments, purge duration may depend, for example, on gas flow within the chamber. For example, gas flow within a chamber that is predominantly laminar may permit removal of remaining gaseous ligands and/or ammonia at a faster rate, while gas flow within a chamber that is predominantly turbulent may permit removal of remaining ligands at a slower rate. It should be noted that claimed subject matter is intended to embrace purging of remaining gaseous material without regard to flow characteristics within a chamber, which may increase or decrease a rate at which gaseous material is removed.

As shown in FIG. 13C, (embodiment 1303) a second gaseous precursor, such as precursor BY of expressions (6a) and (6b), may be introduced into the chamber. As previously mentioned, a second gaseous precursor may comprise an oxidizer, which may operate to displace a first ligand, such as (Cp)₂, for example, and replace the ligand with an oxidizer, such as oxygen (O₂), ozone (O₃), nitric oxide (NO), hydrogen peroxide (H₂O₂), just to name a few examples. Accordingly, as shown in FIG. 13C, oxygen atoms may form bonds with at least some nickel atoms bonded to substrate 1350 in addition to displace a relatively small number of ammonia (NH₃), for example. In an embodiment, precursor BY may oxidize (Ni(Cp)₂) to form a number of additional oxidizers, and/or combinations thereof, in accordance with expression (12) below:

Ni(C₅H₅)₂+O₃→NiO+potential byproducts (e.g., CO, CO₂, C₅H₅, C₅H₆, CH₃, CH₄, C₂H₅, C₂H₆, NH₃ . . . ) (12)

Wherein C₅H₅ has been substituted for Cp in expression (12). In accordance with FIG. 4C, a number of potential byproducts are shown, including C₂H₅, CO₂, CH₄, and C₅H₆. As is also shown in FIG. 13C, ammonia (NH₃) may remain bonded to nickel oxide complexes, such as at sites 1360 in 1361, for example. In embodiments, such nickel-to-ammonia bonds (e.g., NiO:NH₃), in an atomic concentration of between, for example, 0.1% and 10.0% in a fabricated CEM device, may permit electron donation/back-donation which may bring about the substantially rapid conductor/insulator transition of a CEM device.

As shown in FIG. 13D, (embodiment 1304) potential hydrocarbon byproducts, such as CO, CO₂, C₅H₅, C₅H₆, CH₃, CH₄, C₂H₅, C₂H₆, in addition to unreacted ammonia, for example, may be purged from the chamber. In particular embodiments, such purging of the chamber may occur for a duration approximately in the range of 5.0 seconds to 180.0 seconds utilizing a pressure approximately in the range of 0.25 Pa to 100.0 kPa.

In particular embodiments, the sub-processes described shown in FIGS. 13A-13D may be repeated until a desired thickness of correlated electron material, such as a thickness approximately in the range of 200.0 Å to 1000.0 Å is achieved. As previously mentioned herein, atomic layer deposition approaches, such as shown and described with reference to FIGS. 13A-13D, for example, may give rise to a CEM device film comprising a thickness approximately in the range of 0.6 Å to 1.5 Å for example. Accordingly, to construct a CEM device film comprising a thickness of 500.0 Å just as a possible example, approximately 300 to 900 two-precursor cycles, utilizing AX_{gas}+(NH₃ or other ligand comprising nitrogen)+BY_{gas} for example, may be performed. In certain embodiments, cycles may be occasionally interspersed among differing transition metals and/or transition metal oxides to obtain desired properties. For example, in an embodiment, two atomic layer deposition cycles, in which layers of NiO:NH₃ may be formed, may be followed by three atomic layer deposition cycles to form, for example, titanium oxide ammonia complexes (TiO:NH₃). Other interspersing of transition metals and/or transition metal oxides is possible, and claimed subject matter is not limited in this respect.

In particular embodiments, after the completion of one or more atomic layer deposition cycles, a substrate may be annealed, which may assist in controlling grain structure. For example, if atomic layer deposition produces the number of columnar shaped grains, annealing may permit boundaries columnar-shaped grains to grow together which may, for example, reduce resistance and/or enhance electrical current capacity of the relatively impedance state of the CEM device, for example. Annealing may give rise to additional benefits, such as more evenly distributing of nitrogen molecules, such as ammonia; for example, throughout the CEM device material, and claimed subject matter is not limited in this respect.

In embodiments, CEM devices comprising nitrogen-containing dopants may be fabricated utilizing precursor flow profiles as shown and described in reference to FIGS. 9A-9D and temperature profiles as shown and described in reference to FIGS. 10A-10C.

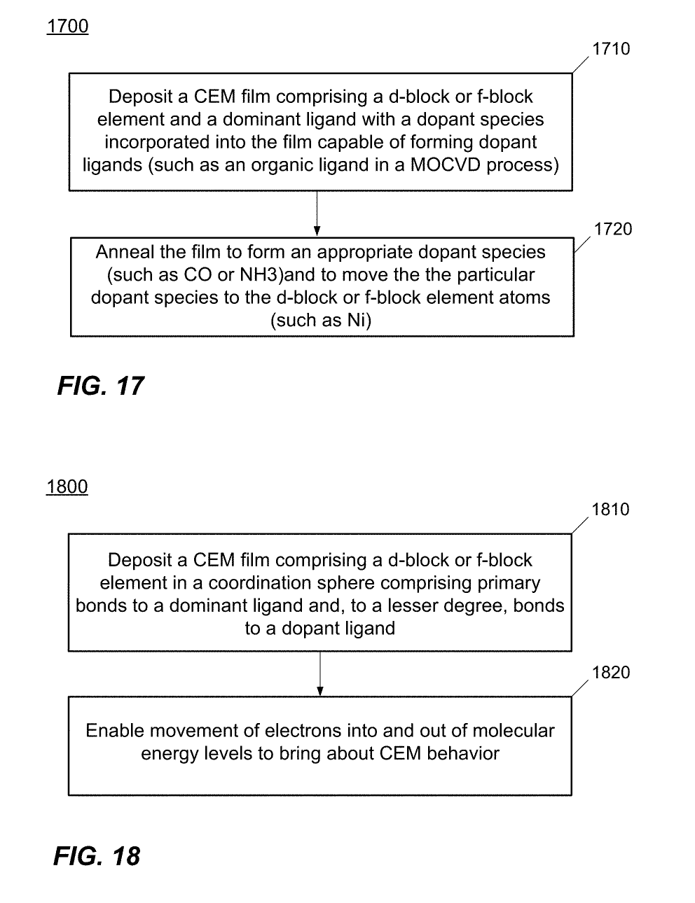

FIGS. 14-18 are flow diagrams of embodiments for additional processes for fabricating correlated electron materials. The method of FIG. 14 (embodiment 1400) may begin at block 1410, which may comprise depositing a film comprising a d-block or f-block element, such as Ni. In embodiments, depositing may comprise PVD (e.g., sputtering which may include plasma and/or may include reactive gases), CVD, MOCVD, ALD, gas cluster ion beam (GCM) deposition, plasma ALD, plasma CVD, and plasma MOCVD, for example. The method may continue at block 1420, which may comprise forming a film comprising the d-block or f-block element and a dominant ligand by oxidizing Ni, for example, to form NiO, for example, or by oxidation/oxynitridation utilizing O₂, O₃, O*, H₂0, NO, N₂O, or NO* sources (wherein the “*” comprises any whole number). At block 1420, the film may be doped with a molecular dopant such as a spectroscopic series ligand such as, for example, O₂²⁻ (oxygen), I⁻ (iodide ion), Br⁻(bromide ion), S²⁻ (sulfur), SCN⁻ (thiocyanate ion, [SCN]⁻ (sulfur-carbon-nitrogen ligand with carbon between), Cl⁻ (chloride ion), N₃⁻ azide, (fluoride ion), NCO⁻ (cyanate), (hydroxide), C₂O₄²⁻ oxalate, H₂O (water), NCS⁻ (isothiocyanate), CH₃CN (acetonitrile), C₅H₅N (py or pyridine), NH₃, ethylenediamine (C₂H₄(NH₂)₂), bipy (2,2′-bipyridine), C₁₀H₈N₂ (phen (1,10-phenanthroline)), C₁₂H₈N₂ (phenanthroline), NO₂⁻ nitrite, PPh₃ (triphenylphosphine, or P(C₆H₅)₃), CN⁻ (cyanide ion), and CO. Molecular dopants may also include hydrocarbons, hydrocarbonates, hydroxides, and nitrogen complexes such as molecules in which CₓH_{y}O_{z} where x, y, and z are integers and: at least x or y or z≧1, CₓH_{y}N_{z} where x, y, and z are integers and: at least x or y or z≧1, and NₓO_{y} where x and y are integers and: at least x or y≧1.

Oxidation or oxynitridation may occur at a pressure approximately in the range of 0.01 kPa to 800.0 kPa and at a temperature approximately in the range of 20.0° C. to 1100.0. In particular embodiments, oxidation or oxynitridation may occur at a temperature approximately in the range of 50.0° C. to 900.0° C. In particular embodiments, oxidation or oxynitridation may occur over a time period approximately in the range of 1.0 seconds to 5.0 hours but may, in certain embodiments, occur approximately in the range of 1.0 seconds to 60.0 min. At block 1430, a CEM film may be doped with a dopant ligand, such as by utilizing a carbon-based source, such as methane (CH₄). At block 1440, the film may be annealed to form a particular dopant species such as, for example, CO or NH₃. High-temperature annealing or annealing at the same temperature or lower temperature than the deposition temperature may be performed utilizing a temperature approximately in the range of 20.0° C. (T_{low}) to 900.0° C., (T_{high}). However, in particular embodiments, smaller ranges may be utilized, such as temperature ranges approximately in the range of 100.0° C. (T_{low}) to 800.0° C. (T_{high}). At block 1450, additional annealing may be performed using temperatures similar to those used at block 1440, but may, at least in particular embodiments, utilize differing temperature ranges. Annealing at block 1450 may operate to move particular dopant species molecules (such as CO or NH₃) to the atoms of the d-block or f-block element.

The method of FIG. 15 (embodiment 1500) may begin at block 1510, which may comprise depositing a film comprising a d-block or f-block element, such as Ni, and a dominant ligand so that a coordination sphere is formed, such as NiO. In particular embodiments, a coordination sphere may include vacancies of the dominant ligand, such as oxygen vacancies. At block 1520, the film may be doped with a molecular dopant such as a spectroscopic series ligand such as those described with respect to block 1420. At block 1530, the film may be annealed to form a particular dopant species, such as CO or NH₃. At block 1540, the film may be annealed to move the particular dopant species, such as CO or NH₃ to the d-block or f-block element atoms.

The method of FIG. 16 (embodiment 1600) may begin at block 1610, which may comprise depositing a film comprising a d-block or f-block element, such as Ni, and a molecular dopant, such as those described with respect to block 1420, with a dopant species incorporated in the film. In embodiments, the dopant species incorporated into the film may be capable of forming dopant ligands, such as an organic ligand in a MOCVD process. An organic ligand MOVCD process may utilize a beta-diketonate type such as bis(2,4-penta nedionato) or acetylacetonato (acac), 1,1,1,5,5,5-hexafluoroacetylacetonato (hfac), 2,2,6,6-tetramethyl-3,5,-heptanedionato (thd), the cyclopentadienyl type such as cyclopentadienyl (Cp), and its ethyl and methyl derivatives, (MeCp), (CpEt) and alkoxy group type such as ethoxy (OEt), methoxy (OMe), and isopropoxy (OⁱPr). At block 1630, the film may be annealed to move the particular dopant species, such as CO or NH₃, to the d-block or f-block element atom (such as Ni).

The method of FIG. 17 (embodiment 1700) may begin at block 1710, which may comprise depositing a film comprising a d-block or f-block element, such as Ni, and a molecular dopant, such as those described with respect to block 1420, with a dopant species incorporated in the film. In embodiments, the dopant species incorporated into the film may be capable of forming dopant ligands (such as an organic ligand in a MOCVD process). At block 1720, the film may be annealed to move the particular dopant species, such as CO or NH₃, to the d-block or f-block element atom (such as Ni).

The method of FIG. 18 (embodiment 1800) may include block 1810, which may comprise depositing a d-block or f-block element in a coordination sphere comprising primary bonds to a dominant ligand. The coordination sphere may comprise, to a lesser degree, bonds to a molecular dopant such as those described with respect to block 1420. Block 1820, which may occur during operation of the CEM device, may comprise enabling movement of electrons into and out of molecular energy levels to bring about CEM behavior. Such behavior may comprise switching between a low-impedance state and a high-impedance state of the CEM device.

In particular embodiments, CEM devices may be implemented in any of a wide range of integrated circuit types. For example, numerous CEM devices may be implemented in an integrated circuit to form a programmable memory array, for example, that may be reconfigured by changing impedance states for one or more CEM devices, in an embodiment. In another embodiment, programmable CEM devices may be utilized as a non-volatile memory array, for example. Of course, claimed subject matter is not limited in scope to the specific examples provided herein.

A plurality of CEM devices may be formed to bring about integrated circuit devices, which may include, for example, a first correlated electron device having a first correlated electron material and a second correlated electron device having a second correlated electron material, wherein the first and second correlated electron materials may comprise substantially dissimilar impedance characteristics that differ from one another. Also, in an embodiment, a first CEM device and a second CEM device, comprising impedance characteristics that differ from one another, may be formed within a particular layer of an integrated circuit. Further, in an embodiment, forming the first and second CEM devices within a particular layer of an integrated circuit may include forming the CEM devices at least in part by selective epitaxial deposition. In another embodiment, the first and second CEM devices within a particular layer of the integrated circuit may be formed at least in part by ion implantation, such as to alter impedance characteristics for the first and/or second CEM devices, for example.

Also, in an embodiment, two or more CEM devices may be formed within a particular layer of an integrated circuit at least in part by atomic layer deposition of a correlated electron material. In a further embodiment, one or more of a plurality of correlated electron switch devices of a first correlated electron switch material and one or more of a plurality of correlated electron switch devices of a second correlated electron switch material may be formed, at least in part, by a combination of blanket deposition and selective epitaxial deposition. Additionally, in an embodiment, first and second access devices may be positioned substantially adjacently to first and second CEM devices, respectively.

In a further embodiment, one or more of a plurality of CEM devices may be individually positioned within an integrated circuit at one or more intersections of electrically conductive lines of a first metallization layer and electrically conductive lines of a second metallization layer, in an embodiment. One or more access devices may be positioned at a respective one or more of the intersections of the electrically conductive lines of the first metallization layer and the electrically conductive lines of the second metallization layer, wherein the access devices may be paired with respective CEM devices, in an embodiment.

In the preceding description, in a particular context of usage, such as a situation in which tangible components (and/or similarly, tangible materials) are being discussed, a distinction exists between being “on” and being “over.” As an example, deposition of a substance “on” a substrate refers to a deposition involving direct physical and tangible contact without an intermediary, such as an intermediary substance (e.g., an intermediary substance formed during an intervening process operation), between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact, but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under” are understood in a similar manner as the terms “up,” “down,” “top,” “bottom,” and so on, previously mentioned. These terms may be used to facilitate discussion, but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes a flip chip, as one illustration, in which, for example, orientation at various times (e.g., during fabrication) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second,” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques, even if those reasonable alternative techniques do not provide identical values, identical measurements or identical results, unless otherwise expressly indicated.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be predominantly present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present disclosure merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

In the preceding description, various aspects of claimed subject matter have been described. For purposes of explanation, specifics, such as amounts, systems, and/or configurations, as examples, were set forth. In other instances, well-known features were omitted and/or simplified so as not to obscure claimed subject matter. While certain features have been illustrated and/or described herein, many modifications, substitutions, changes, and/or equivalents will occur to those skilled in the art. It is, therefore, to be understood that the appended claims are intended to cover all modifications and/or changes as fall within claimed subject matter.

What is claimed is:

1. A method of constructing a device, comprising:
forming, in a chamber, one or more layers of correlated electron material (CEM) on a substrate, the one or more layers of CEM being formed from a transition metal and a dominant ligand, the one or more layers of CEM having a concentration of defects in the coordination spheres forming the CEM; and
exposing the one or more layers of CEM to a molecular dopant comprising a substitutional ligand to form a P-type CEM, wherein the molecular dopant comprises one or more of: O₂²⁻ (oxygen), I⁻ (iodide ion), Br⁻ (bromide ion), S²⁻ (sulfur), SCN⁻ (thiocyanate ion, [SCM]⁻ (sulfur-carbon-nitrogen ligand with carbon between), Cl⁻ (chloride ion), N₃⁻ azide, F⁻ (fluoride ion), NCO⁻ (cyanate), (hydroxide), C₂O₄²⁻ oxalate, H₂O (water), NCS⁻ (isothiocyanate), CH₃CN (acetonitrile), C₅H₅N (pyridine), ethylenediamine (C₂H₄(NH₂)₂), bipy (2,2′-bipyridine), C₁₀H₈N₂ (phen (1,10-phenanthroline)), C₁₂H₈N₂ (phenanthroline), NO₂⁻ nitrite, P(C₆H₅)₃ (triphenylphosphine), CN⁻ (cyanide ion), and molecules in which CₓH_{y}O_{z} where x, y, and z are integers and: at least x and y and z≧1, CₓH_{y}N_{z} in which x, y, and z are integers and: at least x or y or z≧1, and NₓO_{y} where x and y are integers and: at least x or y≧1 wherein,
the one or more layers of formed CEM comprise an atomic concentration of the molecular dopant approximately in the range of 0.1% to 10.0%.

2. The method of claim 1, wherein the substitutional ligand operates to reduce the concentration of defects in the coordination spheres forming the CEM, wherein the reduction in the concentration of defects in the coordination spheres inhibits conductive filament formation in the one or more layers of the CEM.

3. The method of claim 1, wherein the transition metal comprises nickel.

4. The method of claim 1, wherein the dominant ligand comprises oxygen, sulfur, selenium or tellurium, or a combination thereof.

5. The method of claim 1, wherein the substitutional ligand comprises carbonyl, ethylene, nitrosonium or ammonia, or any combination thereof.

6. The method of claim 1, wherein the one or more layers of CEM are formed on a conductive substrate.

7. The method of claim 1, wherein the substitutional ligand operates to reduce the concentration of defects in the coordination spheres forming the CEM, and wherein the reduction in the concentration of defects in the coordination spheres increases conductivity of the one or more layers of the CEM.

8. The method of claim 7, wherein the one or more layers of the CEM exhibits electron donation via a sigma bond between the transition metal and the molecular dopant, and wherein the CEM additionally exhibits electron back-donation utilizing a pi bond of the transition metal.

9. A device, comprising:
a conductive substrate; and
one or more layers of correlated electron material (CEM), formed on the substrate, the one or more layers of CEM formed from a transition metal or a transition metal oxide bonded with a dominant ligand, wherein
the one or more layers of CEM comprise a substitutional ligand as a molecular dopant, wherein the molecular dopant comprises one or more of: O₂²⁻ (oxygen), I⁻ (iodide ion), Br⁻ (bromide ion), S²⁻ (sulfur), SCN⁻ (thiocyanate ion, [SCN]⁻ (sulfur-carbon-nitrogen ligand with carbon between), Cl⁻ (chloride ion), N₃⁻ azide, (fluoride ion), NCO⁻ (cyanate), (hydroxide), C₂O₄²⁻ oxalate, H₂O (water), NCS⁻ (isothiocyanate), CH₃CN (acetonitrile), C₅H₅N (pyridine), ethylenediamine (C₂H₄(NH₂)₂), bipy (2,2′-bipyridine), C₁₀H₈N₂ (phen (1,10-phenanthroline)), C₁₂H₈N₂ (phenanthroline), NO₂⁻ nitrite, P(C₆H₅)₃ (triphenylphosphine), CN⁻ (cyanide ion), and molecules in which CₓH_{y}O_{z} where x, y, and z are integers and: at least x and y and z≧1, CₓH_{y}N_{z} in which x, y, and z are integers and: at least x or y or z≧1, and NₓO_{y} where x and y are integers and: at least x or y≧1.

10. The device of claim 9, wherein the molecular dopant operates to inhibit formation of conductive filaments in the one or more layers of transition metal oxide film under an applied voltage.

11. The device of claim 10, wherein the one or more layers of CEM exhibit electron donation comprising donation of one or more electrons via a sigma bond between the transition metal and the substitutional ligand.

12. The device of claim 11, wherein the one or more layers of CEM exhibit electron back-donation to occur via a pi bond of the transition metal or transition metal oxide.

13. The device of claim 9, wherein the transition metal comprises nickel.

14. The device of claim 9, wherein the dominant ligand comprises oxygen, sulfur, selenium or tellurium, or a combination thereof.

15. The device of claim 9, wherein the substitutional ligand comprises carbonyl, ethylene, nitrosonium or ammonia, or any combination thereof.

16. A switching device, comprising:
one or more layers of correlated electron material (CEM), formed on a substrate, the one or more layers of CEM formed from a transition metal or a transition metal oxide bonded with a dominant ligand, wherein
the one or more layers of CEM comprise a substitutional ligand as a p-type molecular dopant to enable the CEM to change between impedance states at least partially in response to a voltage applied across the switching device, wherein the molecular dopant comprises one or more of: O₂²⁻ (oxygen), I⁻ (iodide ion), Br⁻ (bromide ion), S²⁻ (sulfur), SCN⁻ (thiocyanate ion, [SCN]⁻ (sulfur-carbon-nitrogen ligand with carbon between), Cl⁻ (chloride ion), N₃⁻ azide, F⁻ (fluoride ion), NCO⁻ (cyanate), (hydroxide), C₂O₄²⁻ oxalate, H₂O (water), NCS⁻ (isothiocyanate), CH₃CN (acetonitrile), C₅H₅N (pyridine), ethylenediamine (C₂H₄(NH₂)₂), bipy (2,2′-bipyridine), C₁₀H₈N₂ (phen (1,10-phenanthroline)), C₁₂H₈N₂ (phenanthroline), NO₂⁻ nitrite, P(C₆H₅)₃ (triphenylphosphine), CN⁻ (cyanide ion), and molecules in which CₓH_{y}O_{z} where x, y, and z are integers and: at least x and y and z≧1, CₓH_{y}N_{z} in which x, y, and z are integers and: at least x or y or z≧1, and NₓO_{y} where x and y are integers and: at least x or y≧1.

17. The switching device of claim 16, wherein electron donation comprises donation via a sigma bond between transition metal and the substitutional ligand.

18. The switching device of claim 17, wherein the switching device performs a switching function via electron back-donation via a pi bond of the transition metal or transition metal oxide.

19. The switching device of claim 18, wherein the substitutional ligand comprises carbonyl, ethylene, nitrosonium or ammonia, or any combination thereof.

20. A method, comprising:
exposing a substrate, in a chamber, to a first precursor in a gaseous state, the first precursor comprising a transition metal oxide, a transition metal or a transition metal compound, or any combination thereof, and a first ligand;
exposing the substrate to a second precursor in a gaseous state, the second precursor comprising an oxide so as to form a first layer of a film of correlated electron material; and
repeating the exposing of the substrate to the first and second precursors so as to form additional layers of the film of correlated electron material, the film of correlated electronic material exhibiting a first impedance state and a second impedance state, the first impedance state and the second impedance state to be substantially dissimilar from one another.

21. The method of claim 20, wherein the film of correlated electron material comprises an electron back-donating material in an atomic concentration of between 0.1% and 10.0%.

22. The method of claim 21, wherein the electron back-donating material comprises carbonyl.

23. The method of claim 20, further comprising:
purging the chamber of the first precursor for between 0.5 seconds and 180.0 seconds.

24. The method of claim 20, wherein the exposing the substrate to the first precursor occurs over a duration of between 0.5 seconds and 180.0 seconds.

25. The method of claim 20, further comprising repeating the exposing of the substrate between 50 and 900 times.

26. The method of claim 20, further comprising repeating the exposing of the substrate until a thickness of the film of correlated electron material reaches between 1.5 nm and 150.0 nm.

27. The method of claim 20, wherein the first precursor comprises one or more of nickel amidinate (Ni(AMD)), nickel dicyclopentadienyl (Ni(Cp)₂), nickel diethylcyclopentadienyl (Ni(EtCp)₂), Bis(2,2,6,6-tetramethylheptane-3,5-dionato)Ni(II) (Ni(thd)₂), nickel acetyl acetonate (Ni(acac)₂), bis(methylcyclopentadienyl)nickel (Ni(CH₃C₅H₄)₂), nickel dimethylglyoximate (Ni(dmg)₂), nickel 2-amino-pent-2-en-4-onato (Ni(apo)₂), Ni(dmamb)₂ (in which dmamb=1-dimethylamino-2-methyl-2-butanolate), Ni(dmamp)₂ (in which dmamp=1-dimethylamino-2-methyl-2-propanolate), Bis(pentamethylcyclopentadienyl)nickel (Ni(C₅(CH₃)₅)₂) or nickel carbonyl (Ni(CO)₄), or any combination thereof, in a gaseous state.

28. The method of claim 20, wherein the second precursor comprises oxygen (O₂), ozone (O₃), water (H₂O), nitric oxide (NO), nitrous oxide (N₂O) or hydrogen peroxide (H₂O₂), or any combination thereof.

29. The method of claim 20, wherein the exposing of the substrate to the first precursor, the exposing of the substrate to a second precursor, or any combination thereof, occurs at a temperature of between 20.0° and 1000.0° C.

30. The method of claim 20, additionally comprising annealing the exposed substrate in the chamber.

31. The method of claim 30, further comprising raising a temperature of the chamber to between 20.0° C. and 900.0° C. prior to initiating the annealing.

32. The method of claim 30, wherein the exposed substrate is annealed in an environment comprising one or more of gaseous nitrogen (N₂), hydrogen (H₂), oxygen (O₂), water or steam (H₂O), nitric oxide (NO), nitrous oxide (N₂O), nitrogen dioxide (NO₂), ozone (O₃), argon (Ar), helium (He), ammonia (NH₃), carbon monoxide (CO), methane (CH₄), acetylene (C₂H₂), ethane (C₂H₆), propane (C₃H₈), ethylene (C₂H₄) or butane (C₄H₁₀), or any combination thereof.

33. A film deposited on a substrate, comprising:
a correlated electron material having an approximate thickness of between 1.0 nm and 100.0 nm, the film exhibiting a ratio of a first impedance state to a second impedance state of at least 5.0:1.0 at least partially in response to a voltage of between of 0.1 V and 10.0 V to be applied across a thickness dimension of the film.

34. The film deposited on the substrate according to claim 33, wherein the voltage to be applied is between 0.1 V and 2.0 V, and wherein the correlated electron material comprises a thickness of between 1.5 nm and 150.0 nm.

35. The film deposited on the substrate according to claim 33, wherein the correlated electron material comprises between 10 and 1000 atomic layers.

36. The film deposited on the substrate according to claim 33, wherein at least 50.0% of the substrate comprises a nitride material.

37. A switching device, comprising:
a correlated electron material disposed between two or more conductive electrodes, the correlated electron material having a thickness of between approximately 1.0 nm and approximately 100.0 nm, the switching device to exhibit a ratio of a first impedance state relative to a second impedance state of at least 5.0:1.0 at least partially in response to a voltage of between 0.1 V and 10.0 V to be applied across at least two of the two or more conductive electrodes.

38. The switching device of claim 37, wherein the correlated electron material comprises a thickness of between 1.5 nm and 150.0 and wherein the voltage to be applied across the at least two of the two or more conductive electrodes is to be between 0.6 V and 1.5 V.

39. The switching device of claim 37, wherein the correlated electron material comprises a thickness of between 1.5 nm and 150.0 and is deposited on an electrode materials comprising titanium nitride, platinum, titanium, copper, aluminum, cobalt, nickel, tungsten, tungsten nitride, cobalt silicide, ruthenium oxide, chromium, gold, palladium, indium tin oxide, tantalum, silver or iridium, or any combination thereof.

40. A method, comprising:
in a chamber, exposing a substrate to one or more gases comprising a transition metal oxide or a transition metal, or any combination thereof, and a first ligand, the one or more gases comprising an atomic concentration of a ligand comprising nitrogen so as to bring about an atomic concentration of nitrogen in a fabricated correlated electron material of between 0.1% and 10.0%;
exposing the substrate to a gaseous oxide to form a first layer of a film of the correlated electron material; and
repeating the exposing of the substrate to the one or more gases and to the gaseous oxide so as to form additional layers of the film of the correlated electron material, the film of the correlated electron material exhibiting a first impedance state and a second impedance state substantially dissimilar from one another.

41. The method of claim 40, wherein the first layer of the film of correlated electron material comprises an electron back-donating material.

42. The method of claim 41, wherein the electron back-donating material comprises ammonia (NH₃), ethylene diamine (C₂H₈N₂), nitric oxide (NO), nitrogen dioxide (NO₂), an NO₃ ligand, an amine, an amide or an alkylamide, or any combination thereof.

43. The method of claim 40, further comprising:
purging the chamber of the one or more gases for between 5.0 seconds and 180.0 seconds.

44. The method of claim 40, wherein the exposing the substrate to one or more gases occurs over a duration of between 5.0 seconds and 180.0 seconds.

45. The method of claim 40, further comprising repeating the exposing of the substrate between 50 and 900 times.

46. The method of claim 45, further comprising repeating the exposing of the substrate until a thickness of the film of the correlated electron material reaches between 1.5 nm and 150.0 nm.

47. The method of claim 40, wherein the one or more gases comprises nickel amidinate (Ni(AMD)), nickel dicyclopentadienyl (Ni(Cp)₂), nickel diethylcyclopentadienyl (Ni(EtCp)₂), Bis(2,2,6,6-tetramethylheptane-3,5-dionato)Ni(II) (Ni(thd)₂), nickel acetyl acetonate (Ni(acac)₂), bis(methylcyclopentadienyl)nickel (Ni(CH₃C₅H₄)₂), nickel dimethylglyoximate (Ni(dmg)₂), nickel 2-amino-pent-2-en-4-onato (Ni(apo)₂), Ni(dmamb)₂ (in which dmamb=1-dimethylamino-2-methyl-2-butanolate), Ni(dmamp)₂ (in which dmamp=1-dimethylamino-2-methyl-2-propanolate), Bis(pentamethylcyclopentadienyl)nickel (Ni(C₅(CH₃)₅)₂) or nickel carbonyl (Ni(CO)₄), or any combination thereof, in a gaseous state.

48. The method of claim 40, wherein the gaseous oxide comprises one or more of oxygen (O₂), ozone (O₃), water (H₂O), nitric oxide (NO), nitrous oxide (N₂O) or hydrogen peroxide (H₂O₂), or any combination thereof.

49. The method of claim 40, wherein the exposing of the substrate to one or more of gases and exposing the substrate to the gaseous oxide occurs at a temperature of between 20.0° and 1000.0° C.

50. The method of claim 40, additionally comprising annealing the exposed substrate in the chamber.

51. The method of claim 50, further comprising raising a temperature of the chamber to between 20.0° C. and 900.0° C. prior to initiating the annealing.

52. The method of claim 40, wherein the exposed substrate is annealed in an environment comprising one or more of gaseous nitrogen (N₂), hydrogen (H₂), oxygen (O₂), water or steam (H₂O), nitric oxide (NO), nitrous oxide (N₂O), nitrogen dioxide (NO₂), ozone (O₃), argon (Ar), helium (He), ammonia (NH₃), carbon monoxide (CO), methane (CH₄), acetylene (C₂H₂), ethane (C₂H₆), propane (C₃H₈), ethylene (C₂H₄) or butane (C₄H₁₀), or any combination thereof.

53. A film deposited on a substrate, comprising:
a correlated electron material utilizing nitrogen to provide electron back-donation, the nitrogen comprising an atomic concentration of between 0.1% and 10.0%, the film having an approximate thickness of between 1.0 nm and 100.0 nm and exhibiting a ratio of a first resistance state to a second resistance state of at least 5.0:1.0 at least partially in response to a voltage of between of 0.1 V and 10.0 V to be applied across a thickness dimension of the film.

54. The film deposited on the substrate according to claim 53, wherein the voltage to be applied is between 0.6 V and 1.5 V, and wherein the correlated electron material comprises a thickness of between 10.0 nm and 50.0 nm.

55. The film deposited on the substrate according to claim 53, wherein the correlated electron material comprises between 10 and 1000 atomic layers.

56. The film deposited on the substrate according to claim 53, wherein at least 50.0% of the substrate comprises a nitride material.

57. A switching device, comprising:
a correlated electron material utilizing a nitrogen-based material in an atomic concentration of between 0.1% and 10.0% as an electron back-donating material, the correlated electron material disposed between two or more conductive electrodes, the correlated electron material having a thickness of between 1.0 nm and 100.0 nm and to exhibit a ratio of a first resistance state relative to a second resistance state of at least 5.0:1.0 at least partially in response to a voltage of between 0.1 V and 10.0 V to be applied across at least two of the two or more conductive electrodes.

58. The switching device of claim 57, wherein the correlated electron material comprises a thickness of between 10.0 nm and 50.0 nm and wherein the voltage to be applied across the at least two of the two or more conductive electrodes is to be between 0.6 V and 1.5 V.

59. The switching device of claim 57, wherein the correlated electron material comprises a thickness of between 1.5 nm and 150.0 nm and is deposited on electrode materials of titanium nitride, platinum, titanium, copper, aluminum, cobalt, nickel, tungsten, tungsten nitride, cobalt silicide, ruthenium oxide, chromium, gold, palladium, indium tin oxide, tantalum, silver, iridium, or any combination thereof.
